(19) United States
(12) Patent Application Publication
(10) Pub. No.: US 2024/0237555 A9
(43) Pub. Date: Jul. 11, 2024

(54) SYSTEMS AND METHODS FOR FABRICATION OF SUPERCONDUCTING INTEGRATED CIRCUITS WITH IMPROVED COHERENCE

(71) Applicant: D-WAVE SYSTEMS INC., Bumaby (CA)

(72) Inventors: Colin C. Enderud, Vancouver (CA); Mohammad H. Amin, Coquitlam (CA); Loren J. Swenson, San Jose, CA (US)

(21) Appl. No.: 18/277,688

(22) PCT Filed: Feb. 17, 2022
(86) PCT No.: PCT/US2022/016802

§ 371 Date: Aug. 17, 2023

Related U.S. Application Data
(60) Provisional application No. 63/151,232, filed on Feb. 19, 2021.
(60) Provisional application No. 63/191,708, filed on May 21, 2021.
(60) Provisional application No. 63/194,364, filed on May 28, 2021.

(51) Int. Cl. H10N 60/01; H01L 23/522; H01L 23/532; H01L 25/18; H10N 60/12; H10N 60/80; H10N 69/00

(52) U.S. Cl. CPC H10N 60/0912; H01L 23/5223; H01L 23/5227; H01L 23/53285; H01L 25/18; H10N 60/12; H10N 60/805; H10N 69/00

(57) ABSTRACT

A method of fabrication of a superconducting device includes forming a first portion of the superconducting device on a first chip, a second portion of the superconducting device on a second chip, and bonding the first chip to the second chip, arranged in a flip-chip configuration. The first portion of the superconducting device on the first chip includes a dissipative portion of the superconducting device. A multi-layer superconducting integrated circuit is implemented so that noise-susceptible superconducting devices are positioned in wiring layers formed from a low-noise superconductive material and that underlie wiring layers that are formed from a different superconductive material. A superconducting integrated circuit has a first stack with a first superconducting wiring layer formed from a first high kinetic inductance material and a second superconducting wiring layer communicatively coupled to the first superconducting wiring layer to form a first control circuit, a second stack comprising a third superconducting wiring layer formed from a second high kinetic inductance material and a fourth superconducting wiring layer communicatively coupled the third superconducting wiring layer to form a second control circuit. The superconducting integrated circuit also has a third stack with a controllable device, and at least one of the first control circuit and the second control circuit is communicatively coupled to the controllable device.

### TECHNICAL FIELD

This disclosure generally relates to systems and methods for fabrication of superconducting integrated circuits for quantum computers, and, more specifically, to systems and methods for fabrication of superconducting integrated circuits with improved coherence.

### BACKGROUND

Superconducting Integrated Circuits Superconductivity is a set of physical properties observed in a material where electrical resistance of the material vanishes and magnetic flux fields are expelled from the material. A material exhibiting these properties is referred to in the present application as a superconductor. A superconductor typically has a characteristic critical temperature below which its electrical resistance drops to zero. A material exhibiting these properties is also referred to in the present application as a superconducting material. A superconducting material may be a superconducting metal, for example. Niobium is a superconducting metal that becomes superconducting below 9.2 K. An electric current in a loop of superconducting material can persist indefinitely with no power source.

An integrated circuit (also referred to in the present application as a chip) is one or more electronic circuits on a single piece (or “chip”) substrate. In some implementations, the substrate is silicon. In other implementations, the substrate is sapphire. Integration of large numbers of devices on a chip can result in circuits that are orders of magnitude smaller, faster, and less expensive than circuits constructed of discrete electronic components.

A superconducting integrated circuit is an integrated circuit that includes superconducting material. A superconducting circuit (e.g., a superconducting integrated circuit) may include one or more superconducting devices. Where the superconducting integrated circuit includes a superconducting quantum processor, a superconducting device of the superconducting integrated circuit may be a superconducting qubit, a coupling device, a readout device, or a flux storage device, for example. Superconducting devices of a superconducting quantum processor are described in more detail with reference to FIGS. 1, 2A, and 2B below.

### Superconducting Processor

A quantum processor may take the form of a superconducting processor. However, superconducting processors can include processors that are not intended for quantum computing. For instance, some embodiments of a superconducting processor may not focus on quantum effects such as quantum tunneling, superposition, and entanglement but may rather operate by emphasizing different principles, such as for example the principles that govern the operation of classical computer processors. However, there may still be certain advantages to the implementation of such superconducting “classical” processors. Due to their natural physical properties, superconducting classical processors may be capable of higher switching speeds and shorter computation times than non-superconducting processors, and therefore it may be more practical to solve certain problems on superconducting classical processors. The present articles and methods are particularly well-suited for use in fabricating both superconducting quantum processors and superconducting classical processors.

### Superconducting Qubits

Superconducting qubits are a type of superconducting quantum device that can be included in a superconducting integrated circuit. Superconducting qubits can be separated into several categories depending on the physical property used to encode information. For example, superconducting qubits may be separated into charge, flux and phase devices. Charge devices store and manipulate information in the charge states of the device. Flux devices store and manipulate information in a variable related to the magnetic flux through some part of the device. Phase devices store and manipulate information in a variable related to the difference in superconducting phase between two regions of the device. Superconducting qubits commonly include at least one Josephson junction. A Josephson junction is a small interruption in an otherwise continuous superconducting current path and is typically realized by a thin insulating barrier sandwiched between two superconducting electrodes. Thus, a Josephson junction may be implemented as a three-layer or “trilayer” structure. Superconducting qubits are further described in, for example, U.S. Pat. Nos. 7,876,248, 8,035,540, and 8,098,179.

### Transmon

A transmon is a type of superconducting charge qubit. A transmon is also referred to in the present application as a transmon qubit. A transmon can be used, for example, in superconducting quantum computers. A transmon can have a lower sensitivity to charge noise than other types of superconducting qubits. A transmon can include a charge qubit in which a pair of superconductors are capacitively shunted in order to decrease a sensitivity of the qubit to charge noise, while maintaining a sufficient anharmonicity for selective qubit control.

A transmon can achieve its reduced sensitivity to charge noise by significantly increasing the ratio of Josephson energy to charging energy relative to a typical charge qubit. The increase can be accomplished through the use of a large shunting capacitor. Energy-level spacings for the transmon can be at least largely independent of an offset charge.

### High-Coherence Qubits

It can be desirable to fabricate qubits with decoherence times on the order of μs. To achieve decoherence times on the order of μs, qubits can be fabricated on integrated circuits having dielectrics with loss tangents less than 10⁻⁶. Suitable materials with a sufficiently low loss tangent include single-crystal silicon (Si) and sapphire. Dielectrics typically used in superconducting integrated circuits (e.g., a dielectric used as an insulating layer) have larger loss tangents. Use of dielectrics having larger loss tangents larger than 10⁻⁶ can be an obstacle to achieving qubits with decoherence times on the order of 1 μs.

High-coherence qubits can be fabricated, for example, on a single-crystal substrate with a single metal layer overlying the substrate.

### Flip-Chip

Flip-chip is a method for interconnecting devices (e.g., integrated circuits) to external circuitry using solder bumps deposited on contact pads. The solder bumps are also referred to in the present application as bump bonds. Bump bonds may include indium, for example, in which case they are also referred to in the present application as indium bump bonds.

In some implementations, bump bonds are deposited on contact pads on a top side of a chip during fabrication. In order to mount the chip to an external circuit (e.g., a circuit board or another chip), the chip is flipped over relative to the external circuit so that an upper surface of the chip faces down, and arranged so that its contact pads align with matching contact pads on an upper surface of the external circuit, and then the solder is reflowed to complete the interconnect. This is in contrast to wire bonding, in which the chip is mounted upright, and wires are used to interconnect contact pads to external circuitry.

### Etching

Etching removes layers of, for example, substrates, dielectric layers, oxide layers, electrically insulating layers and/or metal layers according to specified patterns delineated by photoresists or other masking techniques. Two exemplary etching techniques are wet chemical etching and dry chemical etching.

### Planarization

The use of chemical-mechanical planarization (CMP) allows for a nearly flat surface to be produced. CMP is a standard process in the semiconductor industry. The CMP process uses an abrasive and corrosive chemical slurry in conjunction with a polishing pad and retaining ring that are pressed together by a dynamic polishing head. This removes material and tends to even out any irregular topography, making the wafer flat or planar.

### Hamiltonian Description of a Quantum Processor

In accordance with some embodiments of the present articles and methods, a quantum processor may be designed to perform adiabatic quantum computation and/or quantum annealing. A common problem Hamiltonian includes first component proportional to diagonal single qubit terms and a second component proportional to diagonal multi-qubit terms. The problem Hamiltonian, for example, may be of the form:

$${H}_{P} ∝ - \frac{ε}{2} [ {\sum }_{i = 1}^{N} {h}_{i} {σ}_{i}^{z} + {\sum }_{j > i}^{N} {J}_{ij} {σ}_{i}^{z} {σ}_{j}^{z} ]$$

where N represents the number of qubits, σ^{z}ᵢ is the Pauli z-matrix for the i^{th} qubit, hᵢ and J_{i,j} are dimensionless local fields for the qubits, and couplings between qubits, and ε is some characteristic energy scale for Hₚ. Here, the σ^{z}ᵢ and σ^{z}ᵢ σ^{z}ⱼ terms are examples of “diagonal” terms. The former is a single qubit term and the latter a two qubit term. Hamiltonians may be physically realized in a variety of different ways, for example, by an implementation of superconducting qubits.

### Quantum Processor

A quantum processor may take the form of a superconducting quantum processor. A superconducting quantum processor may include a number of superconducting qubits and associated local bias devices. A superconducting quantum processor may also include coupling devices (also known as couplers or qubit couplers) that selectively provide communicative coupling between qubits.

Superconducting qubits are solid state qubits based on circuits of superconducting materials. Operation of superconducting qubits is based on the underlying principles of magnetic flux quantization, and Josephson tunneling. Superconducting effects can be present in different configurations and can give rise to different types of superconducting qubits including flux, phase, charge, and hybrid qubits. The different configurations can vary in the topology of the loops, the placement of the Josephson junctions, and the physical parameters of elements of the superconducting circuits, such as inductance, capacitance, and Josephson junction critical current.

In one implementation, the superconducting qubit includes a superconducting loop interrupted by a Josephson junction. The inductance and the critical current may be selected, adjusted, or tuned, to increase the ratio of the inductance of the Josephson junction to the geometric inductance of the superconducting loop, and to cause the qubit to be operable as a bistable device. In some implementations, the ratio of the inductance of the Josephson junction to the geometric inductance of the superconducting loop of a qubit is approximately equal to three.

In one implementation, the superconducting coupler includes a superconducting loop interrupted by a Josephson junction. The inductance and the critical current may be selected, adjusted, or tuned, to decrease the ratio of the inductance of the Josephson junction to the geometric inductance of the superconducting loop, and to cause the coupler to be operable as a monostable device. In some implementations, the ratio of the inductance of the Josephson junction to the geometric inductance of the superconducting loop of a coupler is approximately equal to, or less than, one.

Further details and embodiments of quantum processors that may be used in conjunction with the present systems and devices are described in, for example, U.S. Pat. Nos. 7,533,068; 8,008,942; 8,195,596; 8,190,548; and 8,421,053.

### Noise in a Quantum Processor

A quantum processor may require a local bias to be applied on a qubit to implement a problem Hamiltonian. The local bias applied on the qubit depends on persistent current I_{P} and external flux bias ϕ_{q} as described below:

δhᵢ=2|Iₚ|δϕ_{q}

Noise affects the local bias δhᵢ in the same way as the external flux bias ϕ_{q} and thus change the specification of the qubit terms in the problem Hamiltonian. By altering the problem Hamiltonian, noise may introduce errors into the computational result from quantum annealing.

Low-noise is a desirable characteristic of quantum devices. Noise can compromise or degrade the functionality of the individual devices, such as superconducting qubits, and of the superconducting processor as a whole. Noise can negatively affect qubit coherence and reduce the efficacy of qubit tunneling. Since noise is a serious concern to the operation of quantum processors, measures should be taken to reduce noise wherever possible so that a transition from coherent to incoherent tunneling is not induced by the environment.

Impurities may be deposited on the metal surface and/or may arise from an interaction with the etch/photoresist chemistry and the metal. Noise can be caused by impurities on the upper surface of the quantum processor. In some cases, superconducting devices that are susceptible to noise are fabricated in the top wiring layers of a superconducting integrated circuit and are thus sensitive to post-fabrication handling. There is a risk of introducing impurities that cause noise during post-fabrication handling. One approach to reducing noise is using a barrier passivation layer, for example, an insulating layer, to overlie the topmost wiring layer. The use of a barrier passivation layer to minimize noise from impurities on the upper surface of a quantum processor is described in US Patent Application No. 2018/02219150A1.

Noise can also result from an external environment or surrounding circuitry in a superconducting processor. In a quantum processor, flux noise on qubits interferes with properly annealing the quantum processor because of the steep transition between qubit states as the flux bias is swept. Flux noise can be a result of current flowing through wiring of other devices included in the superconducting processor and can have a particularly negative effect on qubits at their respective degeneracy points. For example, flux noise can introduce errors in calculations carried out by the superconducting processor due to inaccuracies in setting flux bias and coupling strength values. Reducing or even eliminating such inaccuracies may be particularly advantageous in using an integrated circuit as part of a quantum processor. Much of the static control error can be designed out of the processor with careful layout and high-precision flux sources, as well as by adding circuitry, such as an on-chip shield, to tune away any non-ideal flux qubit behavior. However, in many cases, limitations in integrated circuit fabrication capabilities can make it difficult to address noise by changing processor layout and adding circuitry. There is therefore a general desire for articles and methods to for fabricating integrated circuits that have reduced flux noise (and thus improved coherence) without having to compromise the quantum processor layout by adding additional layers or circuitry.

The foregoing examples of the related art and limitations related thereto are intended to be illustrative and not exclusive. Other limitations of the related art will become apparent to those of skill in the art upon a reading of the specification and a study of the drawings.

### BRIEF SUMMARY

A method of fabrication of a circuit comprising a superconducting device is described. The method comprises forming a first portion of the superconducting device on a first chip; forming a second portion of the superconducting device on a second chip; and bonding the first chip to the second chip, wherein the forming a first portion of the superconducting device on a first chip includes forming a dissipative portion of the superconducting device on the first chip, and the bonding the first chip to the second chip includes forming a superconductingly electrically communicative coupling between the first chip and the second chip. The superconducting device may be a qubit. The qubit may be a superconducting qubit. The superconducting qubit may be a superconducting flux qubit. The superconducting qubit may be a transmon. The circuit may further comprise two qubits, and the first portion of a superconducting device includes a first portion of a coupling device, the coupling device which is operable to provide communicative coupling between the two qubits. The first chip has an upper surface with at least one contact pad and the second chip has an upper surface with at least one contact pad, and the method further comprises forming a flip-chip configuration in which the first chip is flipped relative to the second chip so that the upper surface of the first chip faces the upper surface of the second chip, and the at least one contact pad of the first chip is aligned with the at least one contact pad of the second chip. Bonding the first chip to the second chip may comprises forming a bump bond between the first chip and the second chip. The bump bond between the first chip and the second chip may be an indium bump bond. Forming a bump bond between the first chip and the second chip may include superconductingly electrically coupling the bump bond to at least two superconducting devices on the first chip. Superconductingly electrically coupling the bump bond to at least two superconducting devices on the first chip may include superconductingly electrically coupling the bump bond to a ground, the ground which is common to each superconducting device of the at least two superconducting devices on the first chip. The method may further comprise: forming a ground plane; and superconductingly electrically coupling at least two superconducting devices on the first chip to the ground plane. The ground plane may be formed in an upper layer of the second chip. Forming a dissipative portion of the superconducting device may include forming a shunt capacitor. The first chip may include a substrate and a single metal layer, and the second chip may include a multi-layer chip. The substrate may comprise at least one of sapphire and single-crystal silicon. The superconducting device may be a qubit, and the qubit control circuit may be formed on the multi-layer chip.

A circuit may comprises: a first chip, the first chip comprising a first portion of a superconducting device; a second chip, the second chip comprising a second portion of the superconducting device; and a bond between the first chip and the second chip, the bond which superconductingly electrically communicatively couples the first portion of the superconducting device to the second portion of the superconducting device, wherein the first portion of the superconducting device is a dissipative portion of the superconducting device. The superconducting device may be a qubit. The qubit may be a superconducting qubit. The superconducting qubit may a superconducting flux qubit. The superconducting qubit may be a transmon. The circuit may further comprise two qubits, and the superconducting device may be a coupling device, the coupling device which is operable to provide communicative coupling between the two qubits. The first chip has an upper surface with at least one contact pad, the second chip has an upper surface with at least one contact pad, and the first chip and the second chip are arranged in a flip-chip configuration in which the first chip is flipped relative to the second chip so that the upper surface of the first chip faces the upper surface of the second chip, and the at least one contact pad on the first chip is aligned with the at least one contact pad on the second chip. The bond may be a bump bond. The bump bond may comprise indium. The bump bond may superconductingly electrically communicatively couple to at least two superconducting devices on the first chip. The bump bond may be superconductingly electrically communicatively coupled to the at least two superconducting devices on the first chip by a ground, the ground which is common to each superconducting device of the at least two superconducting devices on the first chip. The circuit may further comprise a ground plane, the ground plane which is superconductingly electrically coupled to at least two superconducting devices on the first chip. The ground plane may be formed in an upper layer of the second chip. The dissipative portion of the superconducting device may include a shunt capacitor. The first chip may include a substrate and a single metal layer, and the second chip may include a multi-layer chip. The substrate may comprise at least one of sapphire and single-crystal silicon. The second portion of the superconducting device may include a qubit control circuit on the multi-layer chip.

A circuit may comprises: a first chip comprising an upper surface with at least one contact pad, a first substrate and a ground plane overlying the first substrate; and a second chip comprising a second substrate and multiple layers overlying the second substrate, an upper layer of the multi-layer chip comprising an upper surface with at least one contact pad, and a dissipative portion of a superconducting device, wherein the first chip and the second chip are arranged in a flip-chip configuration in which the first chip is flipped relative to the second chip so that the upper surface of the first chip faces the upper surface of the second chip, the first chip is placed in proximity to the second chip, and the ground plane of the first chip is separated from the dissipative portion of the superconducting device by at least one of an air gap and a vacuum. The dissipative portion of the superconducting device may be a shunt capacitor. The first substrate may comprise at least one of sapphire and single-crystal silicon.

A superconducting integrated circuit may comprises: a first superconductive wiring region, the first superconductive wiring region comprising a first material that has a first critical temperature at and below which the first material is superconductive; a second superconductive wiring region overlying the first superconductive wiring region, the second superconductive wiring region comprising the first material; a third superconductive wiring region overlying the second superconductive wiring region, the third superconductive wiring region comprising a second material that has a second critical temperature at and below which the second material is superconductive, the second critical temperature different from the first critical temperature; and a fourth superconductive wiring region overlying the third superconductive wiring region, the fourth superconductive wiring region comprising the second material, wherein the first superconductive wiring region and the second superconductive wiring region each comprise at least a portion of at least one noise-susceptible superconducting device. The first critical temperature may be lower than the second critical temperature. The first material may be a low-noise material. The low-noise material may be aluminum. The second material may be niobium. The at least one noise-susceptible superconducting device may be a qubit. The qubit may be a superconducting flux qubit comprising a loop of the first material interrupted by at least one Josephson junction. The at least one noise-susceptible superconducting device may be a coupler. The coupler may comprise a loop of the first material interrupted by at least one Josephson junction. The fourth superconductive wiring region may contain at least a portion of at least one digital-to-analog converter (DAC). The at least one DAC may comprise a loop of the second material interrupted by at least one Josephson junction. The superconducting integrated circuit may further comprise a kinetic inductance region overlying the third superconductive wiring region, the kinetic inductance region comprising a layer of high kinetic inductance material that has a respective critical temperature at and below which the high kinetic inductance material is superconductive and stores a larger proportion of current energy as kinetic energy than magnetic energy. The high kinetic inductance material may comprise at least one of: titanium nitride and niobium nitride. The superconducting integrated circuit may further comprise a kinetic inductance region disposed within the third superconductive wiring region, the kinetic inductance region comprising a layer of high kinetic inductance material that has a respective critical temperature at and below which the high kinetic inductance material is superconductive and stores a larger proportion of current energy as kinetic energy than magnetic energy. The high kinetic inductance material may comprise at least one of titanium nitride and niobium nitride.

A method of fabricating a superconducting integrated circuit may comprise: forming a first superconductive wiring region comprising a first material that has a first critical temperature at and below which the first material is superconductive; forming a second superconductive wiring region overlying the first superconductive wiring region, the second superconductive wiring region comprising the first material; forming a third superconductive wiring region overlying the second superconductive wiring region, the third superconductive wiring region comprising a second material that has a second critical temperature at and below which the second material is superconductive, the second critical temperature different from the first critical temperature; and forming a fourth superconductive wiring region overlying the third superconductive wiring region, the fourth superconductive wiring region comprising the second material, wherein forming the first superconductive wiring region and the second superconductive wiring region comprises forming at least a portion of at least one noise-susceptible superconducting device. The first critical temperature may be lower than the second critical temperature. The first material may comprise a low-noise material. The low-noise material may comprise aluminum. The second material may comprise niobium. The at least one noise-susceptible superconducting device may comprise at least one of: a qubit and a coupler. The fourth superconductive wiring region may comprise at least a portion of at least one digital-to-analog converter (DAC). The method may further comprise forming a kinetic inductance region overlying the third superconductive wiring region, the kinetic inductance region comprising a layer of high kinetic inductance material that has a respective critical temperature at and below which the high kinetic inductance material is superconductive and causes a larger proportion of current energy stored in the kinetic inductance region to be stored as kinetic energy than magnetic energy. The high kinetic inductance material may comprise at least one of: titanium nitride and niobium nitride. The method further comprises forming a kinetic inductance region disposed within the third superconductive wiring region, the kinetic inductance region comprising a layer of high kinetic inductance material that has a respective critical temperature at and below which the high kinetic inductance material is superconductive and causes a larger proportion of current energy stored in the kinetic inductance region to be stored as kinetic energy than magnetic energy. The high kinetic inductance material may comprise at least one of: titanium nitride and niobium nitride.

A superconducting integrated circuit may comprises: a substrate; a first stack overlying the substrate, the first stack comprising a first superconducting wiring layer formed from a first high kinetic inductance material and a second superconducting wiring layer communicatively coupled to the first superconducting wiring layer to form a first control circuit; a second stack overlying the substrate, the second stack comprising a third superconducting wiring layer formed from a second high kinetic inductance material and a fourth superconducting wiring layer communicatively coupled the third superconducting wiring layer to form a second control circuit, the second stack overlying the first stack; and a third stack overlying the substrate, the third stack comprising a controllable device; wherein at least one of the first control circuit and the second control circuit is communicatively coupled to the controllable device. The first control circuit may comprise a first digital-to-analog converter (DAC) and the second control circuit may comprise a second DAC. The controllable device may be one of a qubit, a coupler, a parameter tuning device connected to a qubit or a coupler, or a readout device for a qubit. The first stack and the second stack may overlie the third stack. The superconducting integrated circuit may further comprise a superconducting shielding layer separating the first stack from the second stack. The superconducting integrated circuit may further comprise a superconducting shielding layer separating the first stack and the second stack from the third stack. At least one of the first stack and the second stack may comprise a Josephson junction layer comprising one or more trilayer Josephson junctions. At least one of the first superconducting wiring layer and the third superconducting wiring layer may be adjacent to the Josephson junction layer. Each of the first stack and the second stack may comprise a respective Josephson junction layer comprising one or more trilayer Josephson junctions. The third stack may comprise a Josephson junction layer comprising one or more trilayer Josephson junctions. Each Josephson junction layer may be formed in a top layer of the respective stack. At least one of the first superconducting wiring layer and the third superconducting wiring layer may comprise a respective Josephson junction formed from the respective high kinetic inductance material. Each of the first superconducting wiring layer and the third superconducting wiring layer may comprise respective a Josephson junction formed from the respective high kinetic inductance material. The first superconducting wiring layer and the third superconducting wiring layer may comprise a respective top layer of the respective stack. The first high kinetic inductance material and the second high kinetic inductance material may have at least 10% of energy stored in the respective high kinetic inductance material stored as kinetic inductance. The first high kinetic inductance material and the second high kinetic inductance material may have respective kinetic inductance fractions of 0.1<α≤1. The first high kinetic inductance material and the second high kinetic inductance material may comprise one of WSi, MoN, NbN, NbTiN, TiN, and granular Aluminum. The superconducting integrated circuit may further comprise a fourth stack comprising a fifth superconducting wiring layer and a sixth superconducting wiring layer, the fifth superconducting wiring layer formed from a third high kinetic inductance material, the fifth superconducting wiring layer and the sixth superconducting wiring layer communicatively coupled to form a third control circuit, the fourth stack overlying the first stack and the second stack. The third stack may comprise multiple controllable devices. The third stack may comprise multiple layers. At least one of the second superconducting wiring layer and the fourth superconducting wiring layer may comprise one of niobium and aluminum. At least one of the first control circuit and the second control circuit may comprise control coupler wiring that extends from the respective one of the first stack or the second stack into the third stack, and wherein at least one of the first control circuit and the second control circuit is communicatively coupled to the controllable device via a galvanic or inductive coupling between the control coupler wiring and the controllable device. The controllable device may comprise controllable coupler wiring that extends from the third stack into the respective one of the first stack or the second stack, and wherein at least one of the first control circuit and the second control circuit is communicatively coupled to the controllable device via a galvanic or inductive coupling between the controllable coupler wiring and the at least one of the first control circuit and the second control circuit. The first control circuit and the second control circuit may each comprise a respective DAC; the first superconducting wiring layer and the third superconducting wiring layer may each include a storage inductor of the respective DAC; the second superconducting wiring layer and the fourth superconducting wiring layer may each include control circuitry for the respective DAC; and each of the first stack and the second stack may comprise one or more Josephson junctions of the respective DAC.

A method of forming a superconducting integrated circuit may comprise: depositing a first superconducting wiring layer comprising a first high kinetic inductance material; depositing a second superconducting wiring layer such that the second superconducting wiring layer is positioned to communicatively couple with the first superconducting wiring layer to form a first control circuit; depositing a third superconducting wiring layer overlying the first superconducting wiring layer and the second superconducting wiring layer, the third superconducting wiring layer comprising a second high kinetic inductance material; depositing a fourth superconducting wiring layer such that the fourth superconducting wiring layer is positioned to communicatively couple with the third superconducting wiring layer to form a second control circuit; and forming a controllable device in an additional layer such that at least one of the first control circuit and the second control circuit is communicatively coupled to the controllable device. The first superconducting wiring layer may be overlying the controllable device. The controllable device may be overlying a substrate. The method may further comprise depositing a superconducting shielding layer to separate the first superconducting wiring layer and the second superconducting wiring layer from the third superconducting wiring layer and the fourth superconducting wiring layer. The method may further comprise depositing at least one superconducting shielding layer to separate the first superconducting wiring layer, the second superconducting wiring layer, the third superconducting wiring layer, and the fourth superconducting wiring layer from the additional layer. Forming a controllable device may include depositing a trilayer. The method may further comprise depositing a trilayer adjacent to one of the first superconducting wiring layer and the third superconducting wiring layer. The method may further comprise depositing a respective trilayer adjacent to each of the first superconducting wiring layer and the third superconducting wiring layer. The trilayer may be overlying the respective superconducting wiring layer. The method may further comprise forming a Josephson junction at least partially within the first high kinetic inductance material of the first superconducting wiring layer. The method may further comprise forming a Josephson junction at least partially within the second high kinetic inductance material of the third superconducting wiring layer. The first superconducting wiring layer may be overlying the second superconducting wiring layer, and the third superconducting wiring layer may be overlying the fourth superconducting wiring layer. The method may further comprise: depositing a fifth superconducting wiring layer overlying the third superconducting wiring layer and the fourth superconducting wiring layer, the fifth superconducting wiring layer comprising a third high kinetic inductance material; and depositing a sixth superconducting wiring layer adjacent to and communicatively coupled with the fifth superconducting wiring layer to form a third control circuit. Forming a controllable device may comprise forming multiple controllable devices. Forming a controllable device may comprise depositing multiple superconducting wiring layers. Forming a controllable device in an additional layer such that at least one of the first control circuit and the second control circuit is communicatively coupled to the controllable device may include depositing coupling wiring that extends from the respective one of the second superconducting wiring layer and the fourth superconducting wiring layer into the additional layer to provide a galvanic or inductive coupling between the coupling wiring and the controllable device. Forming a controllable device in an additional layer such that at least one of the first control circuit and the second control circuit is communicatively coupled to the controllable device may include depositing coupling wiring that extends from the additional layer to the respective one of the second superconducting wiring layer and the fourth superconducting wiring layer to provide a galvanic or inductive coupling between the coupling wiring and the at least one of the first control circuit and the second control circuit. Depositing a first superconducting wiring layer and depositing a third superconducting wiring layer may each comprise at least part of forming at least a portion of a storage inductor of a respective DAC; and depositing a second superconducting wiring layer and a fourth superconducting wiring layer may each comprise at least part of forming at least a portion of control circuitry for the respective DAC. Depositing a first superconducting wiring layer and depositing a third superconducting wiring layer may each comprise at least part of forming at least a portion of a Josephson junction of the respective DAC. The method may further comprise depositing at least a portion of a Josephson junction of the respective DAC in a layer adjacent to each of the first superconducting wiring layer and the third superconducting wiring layer.

In other aspects, the features described above may be combined together in any reasonable combination as will be recognized by those skilled in the art.

### BRIEF DESCRIPTION OF THE SEVERAL VIEWS OF THE DRAWINGS

In the drawings, identical reference numbers identify similar elements or acts. The sizes and relative positions of elements in the drawings are not necessarily drawn to scale. For example, the shapes of various elements and angles are not necessarily drawn to scale, and some of these elements are arbitrarily enlarged and positioned to improve drawing legibility. Further, the particular shapes of the elements as drawn, are not necessarily intended to convey any information regarding the actual shape of the particular elements, and have been solely selected for ease of recognition in the drawings.

FIG. 1 is a schematic diagram of a hybrid computing system including a digital computer coupled to an analog computer, in accordance with the present systems, devices, and methods.

FIG. 2A is a schematic diagram of a circuit of an example superconducting quantum processor, according to the present disclosure.

FIG. 2B is a block diagram of a portion of an example superconducting quantum processor, according to the present disclosure.

FIG. 3 is a schematic diagram of an example implementation of a superconducting circuit, according to the present disclosure.

FIG. 4 is a cross-sectional view of a portion of multilayer fabrication stack of an example implementation of a superconducting integrated circuit, according to the present disclosure.

FIG. 5A is a plan view of a superconducting integrated circuit comprising an interdigitated capacitor, according to the present disclosure.

FIG. 5B is a cross-sectional view of the superconducting integrated circuit of FIG. 5A showing a fabrication stack, according to the present disclosure.

FIG. 5C is a cross-sectional view of the superconducting integrated circuit of FIG. 5A showing another fabrication stack, according to the present disclosure.

FIG. 6 is a schematic diagram of an example implementation of the superconducting circuit of FIG. 4 with a flip-chip configuration, according to the present disclosure.

FIG. 7 is a cross-sectional view of an example implementation of a superconducting integrated circuit with a flip-chip configuration, according to the present disclosure.

FIG. 8 is a cross-sectional view of another example implementation of a superconducting integrated circuit with a flip-chip configuration, according to the present disclosure.

FIG. 9 is a cross-sectional view of another example implementation of a superconducting integrated circuit with a flip-chip configuration, according to the present disclosure.

FIG. 10 is a cross-sectional view of another example implementation of a superconducting integrated circuit with a flip-chip configuration, according to the present disclosure.

FIG. 11 is a sectional view of a portion of an example superconducting integrated circuit comprising superconductive wiring regions arranged for improved coherence, in accordance with the present articles and methods.

FIG. 12 is a schematic diagram that illustrates a portion of an example low-noise superconductive wiring region of a superconducting integrated circuit, in accordance with the present articles and methods.

FIG. 13 is a flowchart that illustrates an example method of fabricating a portion of a superconducting integrated circuit comprising superconductive wiring regions arranged for improved coherence, in accordance with the present articles and methods.

FIG. 14A is a sectional view of a first implementation of a superconducting integrated circuit.

FIG. 14B is a sectional view of a second implementation of a superconducting integrated circuit.

FIG. 14C is a sectional view of a third implementation of a superconducting integrated circuit.

FIG. 14D is a sectional view of a fourth implementation of a superconducting integrated circuit.

FIG. 14E is a sectional view of a fifth implementation of a superconducting integrated circuit.

FIG. 14F is a sectional view of a sixth implementation of a superconducting integrated circuit.

FIG. 14G is a sectional view of a seventh implementation of a superconducting integrated circuit.

FIG. 14H is a sectional view of an eighth implementation of a superconducting integrated circuit.

FIG. 15 is a schematic diagram of an implementation of a Digital to Analog Converter (DAC).

FIG. 16 is a schematic diagram of a second implementation of a DAC.

FIG. 17 is a flowchart illustrating a method for fabricating a superconducting integrated circuit.

### DETAILED DESCRIPTION

### Preamble

In the following description, some specific details are included to provide a thorough understanding of various disclosed implementations and embodiments. One skilled in the relevant art, however, will recognize that embodiments may be practiced without one or more of these specific details, or with other methods, components, materials, etc. In other instances, well-known structures associated with superconductive devices and integrated superconductive circuits have not been shown or described in detail to avoid unnecessarily obscuring descriptions of the implementations or embodiments of the present methods. Throughout this specification and the appended claims, the words “element” and “elements” are used to encompass, but are not limited to, all such structures, systems, and devices associated with superconductive circuits and integrated superconductive circuits.

Unless the context requires otherwise, throughout the specification and claims which follow, the word “comprise” is synonymous with “including,” and is inclusive or open-ended (i.e., does not exclude additional, unrecited elements or acts).

Reference throughout this specification to “one embodiment” “an embodiment”, “another embodiment”, “one example”, “an example”, “another example”, “one implementation”, “another implementation”, or the like means that a particular referent feature, structure, or characteristic described in connection with the embodiment, example, or implementation is included in at least one embodiment, example, or implementation. Thus, the appearances of the phrases “in one embodiment”, “in an embodiment”, “another embodiment” or the like in various places throughout this specification are not necessarily all referring to the same embodiment, example, or implementation. Furthermore, the particular features, structures, or characteristics may be combined in any suitable manner in one or more embodiments, examples, or implementations.

It should be noted that, as used in this specification and the appended claims, the singular forms “a,” “an,” and “the” include plural referents unless the content clearly dictates otherwise. Thus, for example, reference to a circuit including “a device” includes a single device, or two or more devices. It should also be noted that the term “or” is generally employed in its sense including “and/or” unless the content clearly dictates otherwise.

The headings provided herein are for convenience only and do not interpret the scope or meaning of the embodiments.

### Example Computing System

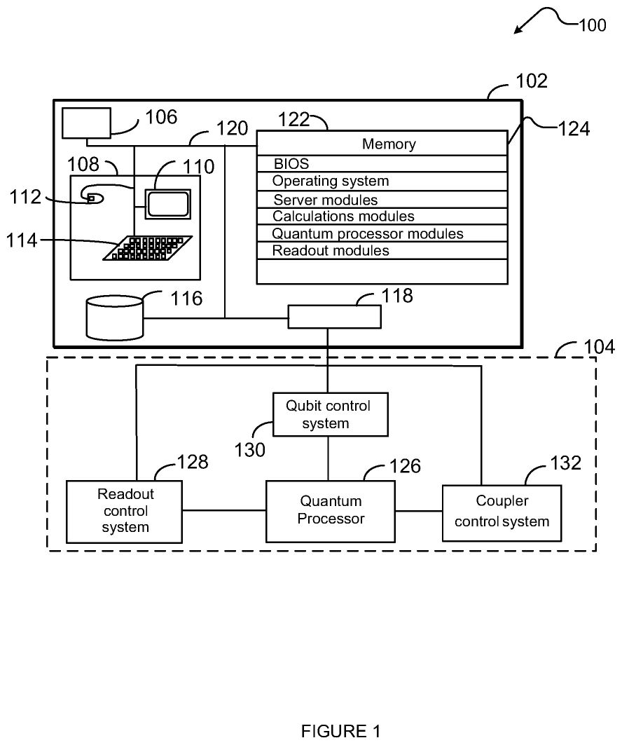

FIG. 1 illustrates a computing system 100 comprising a digital computer 102. The example digital computer 102 includes one or more digital processors 106 that may be used to perform classical digital processing tasks. Digital computer 102 may further include at least one system memory 122, and at least one system bus 120 that couples various system components, including system memory 122 to digital processor(s) 106. System memory 122 may store one or more sets of processor-executable instructions, which may be referred to as modules 124.

The digital processor(s) 106 may be any logic processing unit or circuitry (for example, integrated circuits), such as one or more central processing units (“CPUs”), graphics processing units (“GPUs”), digital signal processors (“DSPs”), application-specific integrated circuits (“ASICs”), programmable gate arrays (“FPGAs”), programmable logic controllers (“PLCs”), etc., and/or combinations of the same.

In some implementations, computing system 100 comprises an analog computer 104, which may include one or more quantum processors 126. Quantum processor 126 may include at least one superconducting integrated circuit fabricated using systems and methods described in the present application. Digital computer 102 may communicate with analog computer 104 via, for instance, a controller 118. Certain computations may be performed by analog computer 104 at the instruction of digital computer 102, as described in greater detail herein.

Digital computer 102 may include a user input/output subsystem 108. In some implementations, the user input/output subsystem includes one or more user input/output components such as a display 110, mouse 112, and/or keyboard 114.

System bus 120 may employ any known bus structures or architectures, including a memory bus with a memory controller, a peripheral bus, and a local bus. System memory 122 may include non-volatile memory, such as read-only memory (“ROM”), static random-access memory (“SRAM”), Flash NAND; and volatile memory such as random-access memory (“RAM”) (not shown).

Digital computer 102 may also include other non-transitory computer- or processor-readable storage media or non-volatile memory 116. Non-volatile memory 116 may take a variety of forms, including: a hard disk drive for reading from and writing to a hard disk (for example, a magnetic disk), an optical disk drive for reading from and writing to removable optical disks, and/or a solid state drive (SSD) for reading from and writing to solid state media (for example NAND-based Flash memory). Non-volatile memory 116 may communicate with digital processor(s) via system bus 120 and may include appropriate interfaces or controllers 118 coupled to system bus 120. Non-volatile memory 116 may serve as long-term storage for processor- or computer-readable instructions, data structures, or other data (sometimes called program modules or modules 124) for digital computer 102.

Although digital computer 102 has been described as employing hard disks, optical disks and/or solid-state storage media, those skilled in the relevant art will appreciate that other types of nontransitory and non-volatile computer-readable media may be employed. Those skilled in the relevant art will appreciate that some computer architectures employ nontransitory volatile memory and nontransitory non-volatile memory. For example, data in volatile memory may be cached to non-volatile memory. Or a solid-state disk that employs integrated circuits to provide non-volatile memory.

Various processor- or computer-readable and/or executable instructions, data structures, or other data may be stored in system memory 122. For example, system memory 122 may store instructions for communicating with remote clients and scheduling use of resources including resources on the digital computer 102 and analog computer 104. Also, for example, system memory 122 may store at least one of processor executable instructions or data that, when executed by at least one processor, causes the at least one processor to execute the various algorithms to execute instructions. In some implementations system memory 122 may store processor- or computer-readable calculation instructions and/or data to perform pre-processing, co-processing, and post-processing to analog computer 104. System memory 122 may store a set of analog computer interface instructions to interact with analog computer 104.

Analog computer 104 may include at least one analog processor such as quantum processor 126. Analog computer 104 may be provided in an isolated environment, for example, in an isolated environment that shields the internal elements of the quantum computer from heat, magnetic field, and other external noise. The isolated environment may include a refrigerator, for instance a dilution refrigerator, operable to cryogenically cool the analog processor, for example to temperature below approximately 1 K.

Analog computer 104 may include programmable elements such as qubits, couplers, and other devices (also referred to herein as controllable devices). Qubits may be read out via readout system 128. Readout results may be sent to other computer- or processor-readable instructions of digital computer 102. Qubits may be controlled via a qubit control system 130. Qubit control system 130 may include on-chip Digital to Analog Converters (DACs) and analog lines that are operable to apply a bias to a target device. Couplers that couple qubits may be controlled via a coupler control system 132. Couple control system 132 may include tuning elements such as on-chip DACs and analog lines. Qubit control system 130 and coupler control system 132 may be used to implement a quantum annealing schedule as described herein on analog processor 104. Programmable elements may be included in quantum processor 126 in the form of an integrated circuit. Qubits and couplers may be positioned in layers of the integrated circuit that comprise a first material. Other devices, such as readout control system 128, may be positioned in other layers of the integrated circuit that comprise a second material.

### Superconducting Quantum Processor

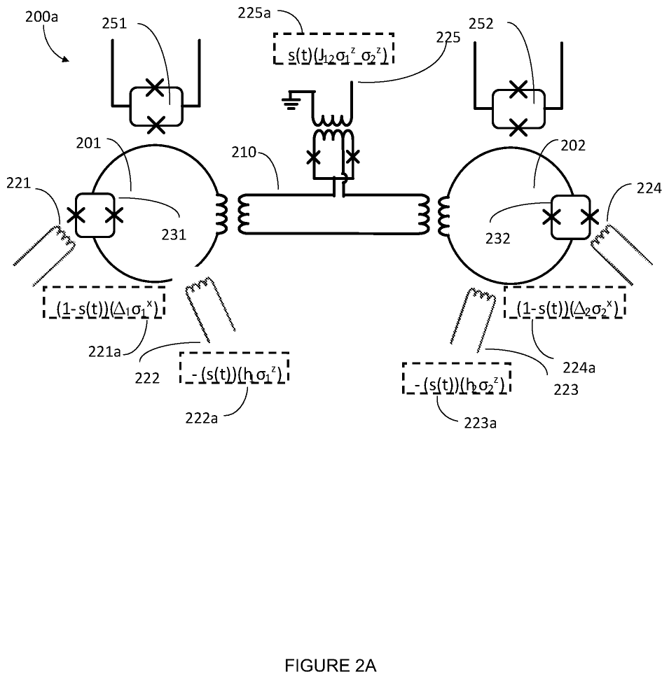

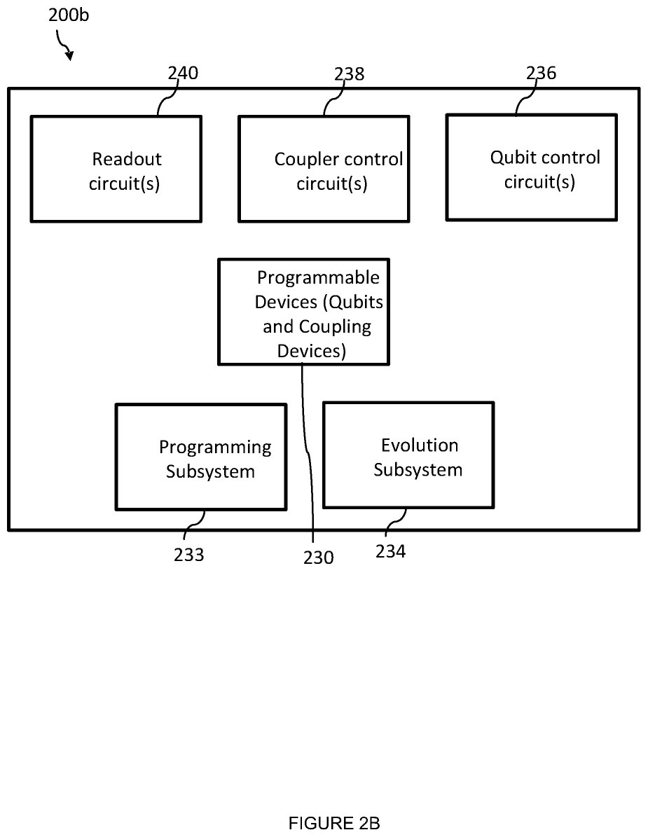

FIG. 2A is a schematic diagram of a circuit 200a of an example superconducting quantum processor, according to at least one implementation. The superconducting quantum processor to which circuit 200a belongs may be used for quantum annealing and/or adiabatic quantum computing, for example. Circuit 200a includes two superconducting qubits 201, and 202. Also shown is a tunable coupling (diagonal coupling) via coupler 210 between qubits 201 and 202 (i.e., providing 2-local interaction). While circuit 200a shown in FIG. 2A includes only two qubits 201, 202 and one coupler 210, those of skill in the art will appreciate that a superconducting quantum processor may include any number of qubits and any number of couplers coupling information between them.

Circuit 200a includes a plurality of interfaces 221-225 that are used to configure and control the state of the superconducting quantum processor. Each of interfaces 221-225 may be realized by a respective inductive coupling structure, as illustrated, as part of a programming subsystem and/or an evolution subsystem. Alternatively, or in addition, interfaces 221-225 may be realized by a galvanic coupling structure. In some implementations, one or more of interfaces 221-225 may be driven by one or more flux storage devices or Digital-to-Analog Converters (DACs). Such a programming subsystem and/or evolution subsystem may be separate from the superconducting quantum processor, or may be included locally (i.e., on-chip with the superconducting quantum processor).

In the operation of the superconducting quantum processor, interfaces 221 and 224 may each be used to couple a flux signal into a respective compound Josephson junction (CJJ) 231 and 232, respectively, of qubits 201 and 202, thereby realizing a tunable tunneling term (the Δᵢ term) in the system Hamiltonian. This coupling provides the off-diagonal σ^{x} terms of the Hamiltonian and these flux signals are examples of “delocalization signals”. Examples of Hamiltonians (and their terms) used in quantum computing are described in greater detail in, for example, U.S. Patent Application Publication No. 2014/0344322.

Similarly, interfaces 222 and 223 may each be used to apply a flux signal into a respective qubit loop of qubits 201 and 202, thereby realizing the hᵢ, terms (dimensionless local fields for the qubits) in the system Hamiltonian. This coupling provides the diagonal σ^{z} terms in the system Hamiltonian. Furthermore, interface 225 may be used to couple a flux signal into coupler 210, thereby realizing the Jᵢⱼ term(s) (dimensionless local fields for the couplers) in the system Hamiltonian. This coupling provides the diagonal σ^{z}ᵢ σ^{z}ⱼ terms in the system Hamiltonian.

In FIG. 2A, the contribution of each of interfaces 221-225 to the system Hamiltonian is indicated in broken line boxes 221a-225a, respectively. As shown, in the example of FIG. 2A, the broken line boxes 221a-225a are elements of time-varying Hamiltonians for quantum annealing and/or adiabatic quantum computing.

Throughout this specification and the appended claims, the term “quantum processor” is used to generally describe a collection of physical qubits (e.g., qubits 201 and 202) and qubit couplers (e.g., coupler 210). The physical qubits 201 and 202 and the coupler 210 are referred to as the “controllable devices” of a quantum processor and their corresponding parameters (e.g., the qubit hᵢ values and the coupler Jᵢⱼ values) are referred to as the “controllable parameters” of the quantum processor. In the context of a quantum processor, the term “programming subsystem” is used to generally describe the interfaces (e.g., “programming interfaces” 222, 223, and 225) used to apply the controllable parameters to the controllable devices of the superconducting quantum processor and other associated control circuitry and/or instructions. In some implementations, programming interfaces 222, 223, and 225 may include DACs. DACs may also be considered programmable devices that are used to control controllable devices such as qubits, couplers, and parameter tuning devices.

As previously described, the programming interfaces of the programming subsystem may communicate with other subsystems which may be separate from the quantum processor or may be included locally on the processor. The programming subsystem may be configured to receive programming instructions in a machine language of the quantum processor and execute the programming instructions to program the programmable and controllable devices in accordance with the programming instructions. Similarly, in the context of a quantum processor, the term “evolution subsystem” generally includes the interfaces (e.g., “evolution interfaces” 221 and 224) used to evolve devices such as the qubits of circuit 200a and other associated control circuitry and/or instructions. For example, the evolution subsystem may include annealing signal lines and their corresponding interfaces (221, 224) to the qubits (201, 202).

Circuit 200a also includes readout devices 251 and 252, where readout device 251 is associated with qubit 201 and readout device 252 is associated with qubit 202. In the example implementation shown in FIG. 2A, each of readout devices 251 and 252 includes a direct current superconducting quantum interference device (DC-SQUID) inductively coupled to the corresponding qubit. In the context of circuit 200a, the term “readout subsystem” is used to generally describe the readout devices 251, 252 used to read out the final states of the qubits (e.g., qubits 201 and 202) in the superconducting quantum processor to produce a bit string. The readout subsystem may also include other elements, such as routing circuitry (e.g., latching elements, a shift register, or a multiplexer circuit) and/or may be arranged in alternative configurations (e.g., an XY-addressable array, an XYZ-addressable array, etc.), any of which may comprise DACs. Qubit readout may also be performed using alternative circuits, such as that described in International (PCT) Patent Application Publication WO2012064974.

While FIG. 2A illustrates only two physical qubits 201, 202, one coupler 210, and two readout devices 251, 252, a quantum processor (e.g., processor comprising circuit 200a) may employ any number of qubits, couplers, and/or readout devices, including a larger number (e.g., hundreds, thousands or more) of qubits, couplers and/or readout devices. The application of the teachings herein to processors with a different (e.g., larger) number of computational components should be readily apparent to those of ordinary skill in the art.

A superconducting quantum processor may include other types of qubits besides superconducting flux qubits. For example, a superconducting quantum processor may include superconducting charge qubits, transmon qubits, and the like. A superconducting qubit may include a shunt capacitor. Examples of qubits that use a shunt capacitor include a three-junction flux qubit, a zero-pi qubit, a fluxonium qubit, a bifluxon qubit, and a transmon. The following description uses the transmon as an example of a superconducting qubit that includes a shunt capacitor. Approaches described in the present application can be applied more generally to other types of qubits, including other types of superconducting qubits that include a shunt capacitor.

FIG. 2B is a block diagram of a portion 200b of an example superconducting quantum processor, according to the present disclosure. Portion 200b of the superconducting quantum processor includes programmable devices 230. Programmable devices 230 includes a collection of qubits and coupling devices, each coupling device operable to communicative couple two or more qubits.

Portion 200b of the superconducting quantum processor also includes a programming subsystem 233, and an evolution subsystem 234 (described above with reference to FIG. 2A). Portion 200b of the superconducting quantum processor also includes qubit control circuit(s) 236, coupler control circuit(s) 238, and readout circuit(s) 240.

### Transmon Qubit

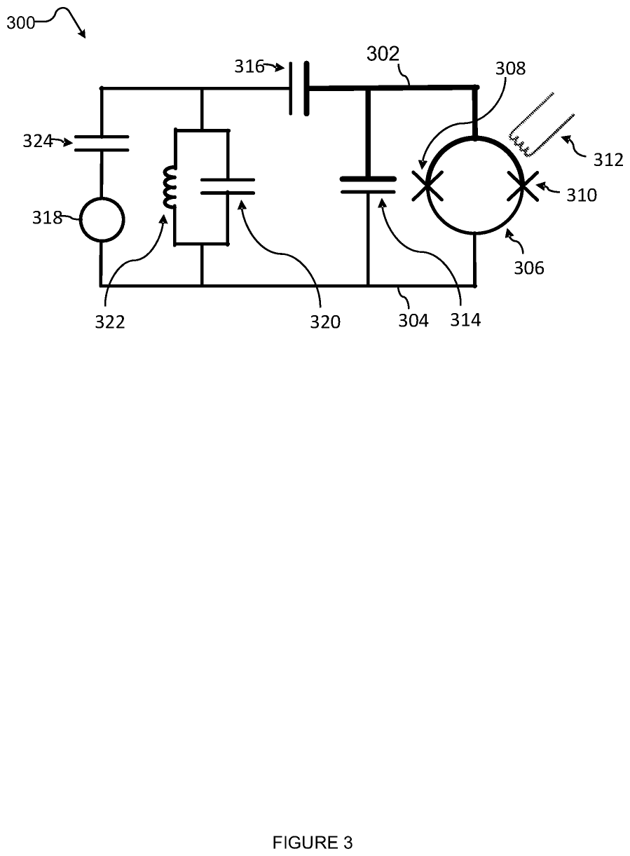

FIG. 3 is a schematic diagram of an example implementation of a superconducting circuit 300, according to the present disclosure. Superconducting circuit 300 is an example of a transmon.

Superconducting circuit 300 includes superconducting island 302 (shown in bold lines) and superconducting island 304 communicatively coupled by a DC-SQUID 306. DC-SQUID 306 includes Josephson junction 308 and Josephson junction 310 coupled in parallel with each other in a superconducting loop. In some implementations, Josephson junctions 308 and 310 are symmetric junctions. A flux bias can be applied to DC-SQUID 306 by interface 312 to tune a Josephson energy of superconducting circuit 300. Superconducting circuit 300 also includes a shunt capacitor 314.

Superconducting circuit 300 can be controlled by a gate electrode capacitively communicatively coupled to superconducting island 302 by gate capacitance 316 with a gate voltage supplied by supply 318. Superconducting circuit 300 further includes a resonator having capacitance 320 and inductance 322, and additional capacitance 324.

### Multilayer Fabrication Stack of Superconducting Quantum Processor

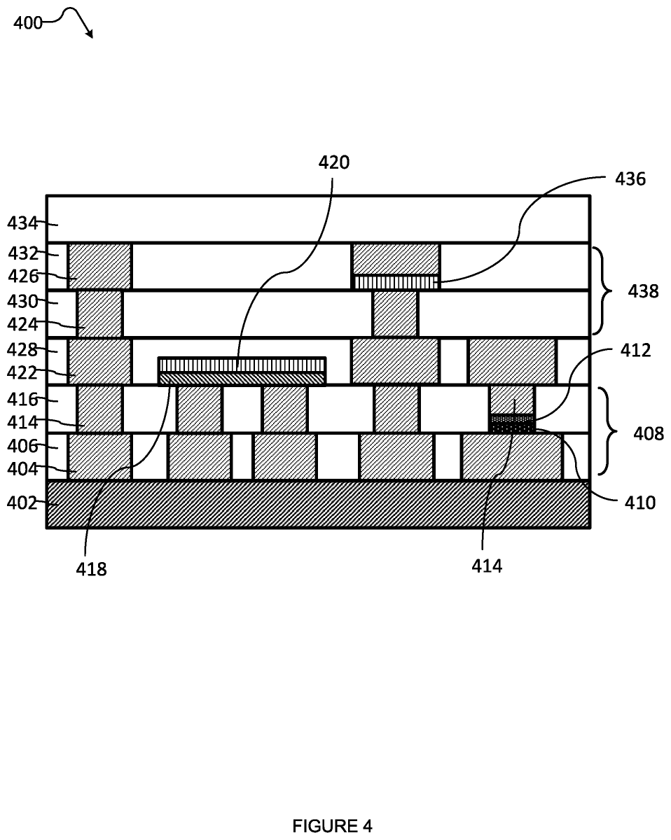

FIG. 4 is a cross-sectional view of a portion 400 of a multilayer fabrication stack of an example implementation of a superconducting integrated circuit, according to the present disclosure. As explained below, portion 400 includes multiple metal layers (e.g., wiring layers) and interlayer dielectrics, vias (vertical interconnect accesses), a Josephson junction, a capacitor, and a kinetic inductor (used, e.g., in a flux storage device). FIG. 4 is a simplified view of portion 400 of the multilayer fabrication stack, and, for clarity of presentation, the features are not shown to scale.

Portion 400 includes a substrate 402, a superconducting metal layer 404 that overlies at least a portion of substrate 402, and a dielectric layer 406 that overlies at least a portion of substrate 402. In some implementations, substrate 402 includes or consists of silicon. In some implementations, superconducting metal layer includes or consists of niobium. In some implementations, dielectric layer 406 includes or consists of silicon dioxide (SiO2). In some implementations, dielectric layer 406 is polished (e.g., by chemical mechanical polishing) back to an upper surface of superconducting metal layer 404.

Portion 400 further includes a Josephson junction 408 formed by a trilayer that includes superconducting metal layer 404 (also referred to in the present application as a base electrode of Josephson junction 408), a superconducting metal layer 410, a metal oxide 412 formed on superconducting metal layer 410, and a superconducting metal layer 414 (also referred to in the present application as a counter-electrode of Josephson junction 408). Portion 400 further includes a dielectric layer 416 overlaying at least a portion of dielectric layer 406 and superconducting metal layer 404.

Portion 400 includes a kinetic inductor 418 formed in a layer of material having a high kinetic inductance. The layer of high kinetic inductance material is also referred to in the present application as a flux storage layer. Patterning the high kinetic inductance layer to form high kinetic inductor 418 can include masking and etching at least a portion of the high kinetic inductance layer. In some implementations, kinetic inductor 418 comprises titanium nitride (TiN). In some implementations, kinetic inductor 418 comprises niobium nitride (NbN). In some implementations, kinetic inductor 418 has a thickness of approximately 50 nm. In some implementations, kinetic inductor 418 is capped by a high-quality dielectric 420, e.g., silicon nitride (SiN). Dielectric 420 may act as a passivation insulating layer to protect kinetic inductor 418.

Portion 400 further includes superconducting metal layer 422, superconducting metal layer 424, and superconducting metal layer 426. Superconducting metal layers 422, 424, and 426 may be superconducting wiring layers patterned to provide one or more superconducting traces, and/or metal layers patterned to provide one or more stud vias (vertical interconnect accesses). Superconducting metal layers 422, 424, and 426 may include or consists of at least one or niobium and aluminum.

Portion 400 further includes interlayer dielectric (ILD) 428, ILD 430, ILD 432, and dielectric layer 434. ILDs 428, 430, and 432, and dielectric layer 434 may include or consist of silicon dioxide, and may be planarized by chemical mechanical polishing, for example.

Portion 400 includes a dielectric layer 436 patterned to form a dielectric of a parallel plate capacitor 438. Dielectric layer 436 may include or consist of SiN, and/or may be 50 nm to 70 nm in thickness.

While FIG. 4 illustrates fabrication of an implementation of a superconducting integrated circuit having an arrangement of layers and devices, other implementations can include layers and devices in various arrangements. For example, in some implementations, a superconducting integrated circuit can include one or more kinetic inductors at one level in the stack, and one or more capacitors at a higher or lower level in the stack. Some implementations include one or more kinetic inductors and one or more capacitors at the same level in the stack. Thus, the kinetic inductor and capacitor can be in the same layer, in different layers, and in either of those implementations the capacitor can include or not include (omit) a flux storage layer.

Integrated Circuit with Single Metal Layer and Interdigitated Capacitor

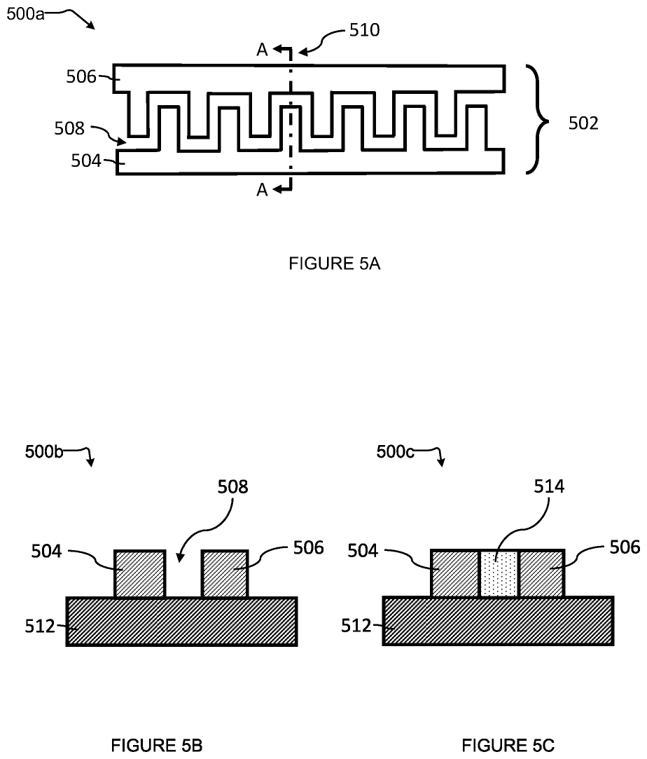

FIG. 5A is a plan view of a superconducting integrated circuit 500a comprising an interdigitated capacitor 502, according to the present disclosure. Capacitor 502 includes two interdigitated electrodes, specifically electrode 504 and electrode 506. Electrodes 504 and 506 are patterned in a layer of superconducting metal. There is a space 508 between electrodes 504 and 506. Space 508 may be filled with air or may be in a vacuum.

FIG. 5B is a cross-sectional view of superconducting integrated circuit 500a of FIG. 5A showing a fabrication stack 500b, according to the present disclosure. The cross-sectional view of FIG. 5B is a cross-section of superconducting integrated circuit 500a of FIG. 5A along a dot-dash line 510 and in a direction indicated by arrows A-A in FIG. 5A.

Fabrication stack 500b includes a superconducting metal layer in which electrodes 504 and 506 are patterned. In some implementations, fabrication stack 500b includes only a single superconducting metal layer. The superconducting metal layer of electrodes 504 and 506 overlies a substrate 512. In some implementations, substrate 512 includes or consists of a material with a low loss tangent. In some implementations, substrate 512 includes or consist of one of single-crystal silicon (Si) and sapphire. In some implementations, electrodes 504 and 506 include or consist of aluminum.

In fabrication stack 500b of FIG. 5B, a magnetic field can be confined either in the air or vacuum of space 508, or in substrate 512. FIG. 5C is a cross-sectional view of superconducting integrated circuit 500a of FIG. 5A showing another fabrication stack 500c, according to the present disclosure. Fabrication stacks 500b and 500c are the same or similar to each other except for the presence in fabrication stack 500c of a dielectric 514 overlying substrate 512, interposed between electrodes 504 and 506, and having a relative permittivity greater than a relative permittivity of air. In some implementations, dielectric 514 includes or consists of a low-loss dielectric. In some implementations, dielectric 514 includes or consists of a dielectric with a loss tangent less than 10⁻⁶.

### Flip-Chip Arrangement for Superconducting Integrated Circuit

One or more dissipative portions (e.g., a capacitor) of a superconducting integrated circuit can be fabricated on one chip, and the remainder of the devices comprising the superconducting integrated circuit can be fabricated on a second, separate chip. The two chips can be assembled in a flip-chip configuration.

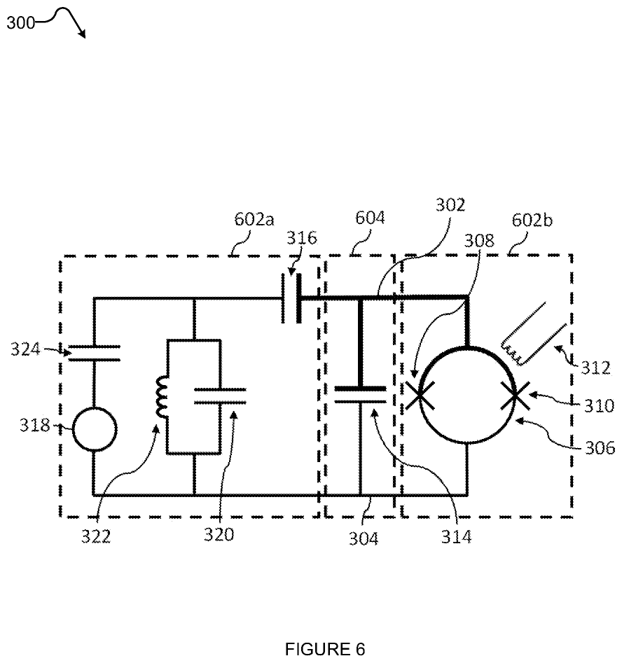

FIG. 6 is a schematic diagram of an example implementation of superconducting circuit 300 of FIG. 3 with a flip-chip configuration, according to the present disclosure. FIG. 6 shows superconducting circuit 300 divided into three portions 602a, 602b, and 604. Portions 602a and 602b are implemented on a multi-layer superconducting chip, and portion 604 is implemented on a flip-chip. In some implementations, the flip-chip includes a substrate and a single metal layer. Portion 604 includes shunt capacitor 314 which communicatively couples superconducting islands 302 and 304.

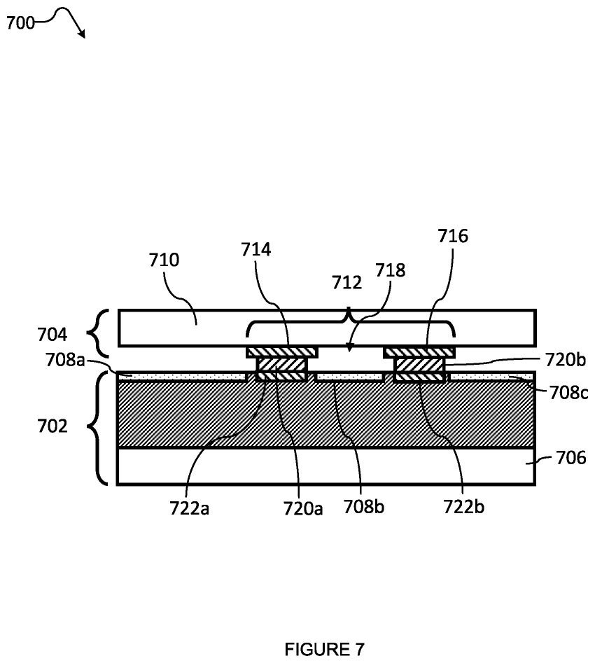

FIGS. 7, 8, 9, and 10 are cross-sectional views of various example implementations of superconducting integrated circuits with a flip-chip configuration. Superconducting integrated circuits 700, 800, 900, and 1000 each include two chips 702 and 704, 802 and 804, 902 and 904, and 1002 and 1004, respectively.

Each of chips 702, 802, 902, and 1002 is a respective multi-layer superconducting integrated circuit, and may include, for example, a portion of a multilayer fabrication stack such as portion 400 of FIG. 4. Each chip may include without limitation, for example, some or all of the following—multiple metal layers (e.g., wiring layers) and interlayer dielectrics, vias (vertical interconnect accesses), Josephson junctions, portions of qubits and/or couplers, flux storage devices, control circuitry and readout circuitry. Control circuitry may include a qubit control circuit, for example.

Each of chips 702, 802, 902, and 1002 includes a substrate 706, a substrate 806, a substrate 906, and a substrate 1006, respectively.

In some implementations, each of chips 702, 802, and 902 includes portions of a ground plane 708a, 708b, and 708c (collectively, ground plane 708), 808a, 808b, and 808c (collectively, ground plane 808), and 908a, 908b, and 908c (collectively, ground plane 908), respectively. In some implementations, ground planes 708, 808, and 908 are formed in an upper layer of chips 702, 802, and 902, respectively.

Each of chips 702, 802, and 902 is shown as a simplified view for clarity of presentation. Features of chips 702, 802, and 902 other than substrates 706, 806, and 906, respectively, and ground planes 708, 808, and 908, respectively, are not detailed.

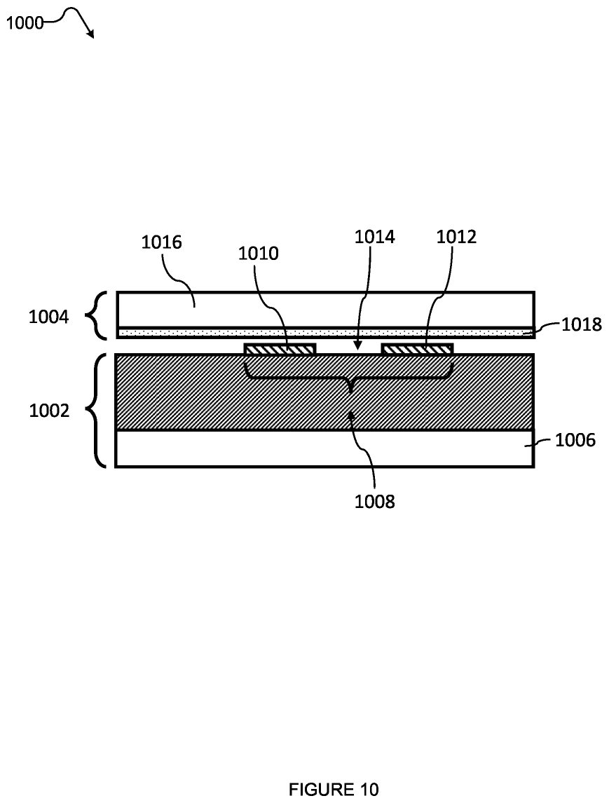

Chip 1002 is also shown as a simplified view for clarity of presentation. Some features of chip 1002 are not detailed in FIG. 10.

FIG. 7 is a cross-sectional view of an example implementation of a superconducting integrated circuit 700 with a flip-chip configuration, according to the present disclosure. The flip-chip configuration of FIG. 7 includes chip 702 comprising a multi-layer superconducting integrated circuit, and chip 704 comprising a substrate 710, and a single metal layer patterned to form a coplanar capacitor 712. In some implementations, substrate 710 includes or consists of sapphire or single-crystal silicon.

Coplanar capacitor 712 includes electrode 714 and electrode 716. In some implementations, electrodes 714 and 716 include or consist of one of niobium and aluminum. Coplanar capacitor 712 includes a space 718 interposed between electrodes 714 and 716. Space 718 may be filled with air or may be in a vacuum. A magnetic field can be confined either in the air or vacuum of space 718, or in substrate 710. In some implementations, space 718 can include a low-loss dielectric (similar to dielectric 514 of FIG. 5C, not shown in FIG. 7). In some implementations, the low-loss dielectric includes or consists of silicon nitride.

Chips 702 and 704 are superconductingly electrically communicatively coupled to each other by bump bonds 720a and 720b (collectively referred to as bump bonds 720). Bump bonds 720a and 720b couple electrodes 714 and 716, respectively, to contact pad 722a and contact pad 722b, respectively, of chip 702. In some implementations, bump bonds 720 include or consist of indium. In some implementations, contact pads 722a and 722b include or consist of one or niobium and aluminum.

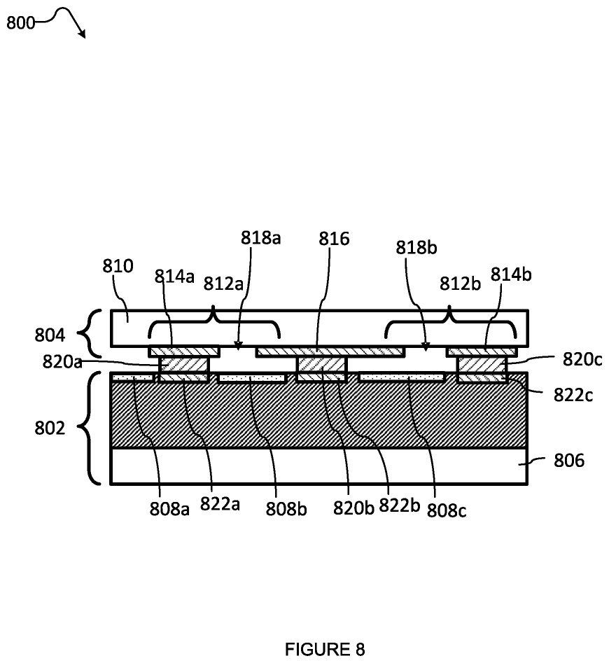

FIG. 8 is a cross-sectional view of another example implementation of a superconducting integrated circuit 800 with a flip-chip configuration, according to the present disclosure. Chip 804 includes a substrate 810, and a single metal layer patterned to form a pair of coplanar capacitors 812a and 812b. Coplanar capacitor 812a includes an electrode 814a and a common electrode 816, and coplanar capacitor 812b includes an electrode 814b and common electrode 816. Electrode 816 is common to both of coplanar capacitors 812a and 812b.

In some implementations, substrate 810 includes or consists of sapphire or single-crystal silicon. In some implementations, electrodes 814a, 814b, and 816 include or consist of one of niobium and aluminum.

Coplanar capacitor 812a includes a space 818a interposed between electrode 814a and common electrode 816. Coplanar capacitor 812b includes a space 818b interposed between electrode 814b and common electrode 816. Spaces 818a and 818b may be filled with air or may be in a vacuum. A magnetic field can be confined either in the air or vacuum of spaces 818a and 818b, or in substrate 810. In some implementations, spaces 818a and 818b can include a low-loss dielectric (similar to dielectric 514 of FIG. 5C, not shown in FIG. 8). In some implementations, the low-loss dielectric includes or consists of silicon nitride.

Chips 802 and 804 are superconductingly electrically communicatively coupled to each other by bump bonds 820a, 820b, and 820c (collectively, bump bonds 820). Bump bonds 820a, 820b, and 820c couple electrodes 814a, 816, and 814b, respectively, to contact pads 822a, 822b, and 822c (collectively, contact pads 822), respectively, on chip 802. In some implementations, bump bonds 820 include or consist of indium. In some implementations, contact pads 822 include or consist of one or niobium and aluminum.

The arrangement of circuit 800, in which there is a bump bond (bump bond 820b) in common with more than one coplanar capacitor (coplanar capacitors 812a and 812b) can be advantageous, for example, by superconductingly electrically communicatively coupling chips 802 and 804 by only one dedicated bump bond per capacitor. The arrangement of circuit 800 has fewer bump bonds overall than an arrangement (for example, the arrangement of circuit 700 of FIG. 7) in which there are two dedicated bump bonds per capacitor.

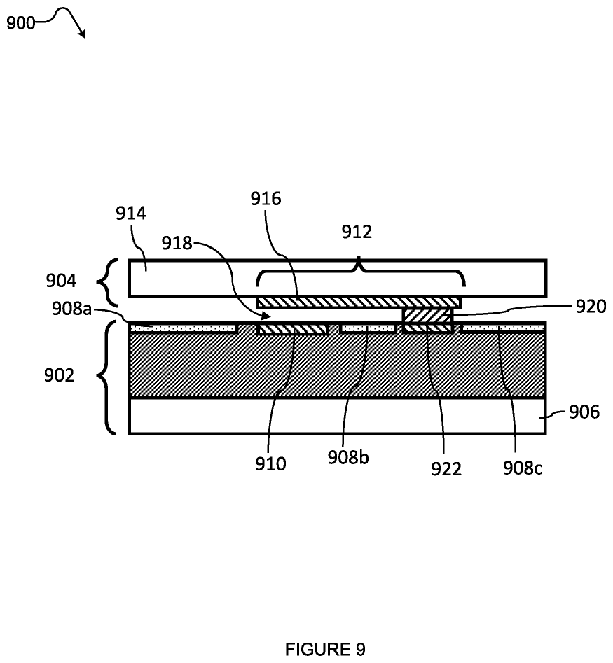

FIG. 9 is a cross-sectional view of another example implementation of a superconducting integrated circuit 900 with a flip-chip configuration, according to the present disclosure. Chip 904 includes a substrate 914, and a single metal layer patterned to form an upper plate 916 of parallel plate capacitor 912. Parallel plate capacitor 912 includes an air gap 918 interposed between lower plate 910 and upper plate 916. In some implementations, substrate 914 includes or consists of one of sapphire and single-crystal silicon. In some implementations, lower plate 910 and upper plate 916 include or consist of one of niobium and aluminum.

Chips 902 and 904 are superconductingly electrically communicatively coupled to each other by bump bond 920 which couples upper plate 916 to contact pad 922 on chip 904. In some implementations, bump bond 920 includes or consists of indium. In some implementations, contact pad 922 includes or consists of one of niobium and aluminum.

FIG. 10 is a cross-sectional view of another example implementation of a superconducting integrated circuit 1000 with a flip-chip configuration, according to the present disclosure. Chip 1002 may include a dissipative portion of a superconducting device, for example, coplanar capacitor 1008. Coplanar capacitor 1008 may be fabricated in an upper layer of chip 1002. Coplanar capacitor 1008 includes electrode 1010 and electrode 1012. A space 1014 is interposed between electrodes 1010 and 1012. Space 1014 may be filled with air or may be in a vacuum. A magnetic field can be confined either in the air or vacuum of space 1014. In some implementations, space 1014 can include a low-loss dielectric (similar to dielectric 514 of FIG. 5C, not shown in FIG. 10). In some implementations, the low-loss dielectric includes or consists of silicon nitride.

Chip 1004 includes a substrate 1016, and a ground plane 1018. Ground plane 1018 may be fabricated in an upper layer of chip 1004 which becomes a layer close to chip 1002 when chip 1004 is flipped during assembly of superconducting integrated circuit 1000. Ground plane 1018 may be separated from a dissipative portion of a superconducting device of chip 1002, for example, coplanar capacitor 1008, by at least one of an air gap and a vacuum.

In some implementations, substrate 1016 includes or consists of one or sapphire and single-crystal silicon. In some implementations, ground plane 1018 includes or consists of one of niobium and aluminum.

Chips 1002 and 1004 may not be superconductingly electrically communicatively coupled by bump bonds. In operation, proximity of ground plane 1018 to chip 1002 can advantageously confine an electric field generated by a device on chip 1002, for example, an electric field generated by coplanar capacitor 1008.

In some implementations, chips 1002 and 1004 may be superconductingly electrically communicatively coupled by one or more bump bonds, for example, to communicatively couple ground plane 1018 of chip 1004 to a ground of superconducting integrated circuit 1000.

In other implementations, chips 704, 804, 904, and 1004 include coupling devices (not shown in FIGS. 7, 8, 9, and 10). In yet other implementations, chips 704, 804, 904, and 1004 include portions of coupling devices, for example, a capacitor.

In some implementations, a pair of superconducting qubits are superconductingly electrically communicatively coupled using traces in a single-metal layer of chips 704, 804, and 904. The pair of superconducting qubits may be superconducting qubits that each include a respective shunt capacitor. In some implementations, each superconducting qubit of the pair of superconducting qubits is one of a three-junction flux qubit, a zero-pi qubit, a fluxonium qubit, a bifluxon qubit, and a transmon qubit. In some implementations, a tunable coupling device includes one or more Josephson junctions fabricated in multi-layer chips 702, 802, and 902, and a capacitive or dissipative portion of the tunable coupling device fabricated on chips 704, 804, and 904, respectively.

### Optimized Coherence Stack

Throughout the present specification, the phrase “noise-susceptible superconducting device” is used to describe a superconducting device for which noise may adversely affect the proper performance in annealing in a quantum processor. Poor performance of a noise-susceptible device may result in the quantum processor producing inaccurate or suboptimal solutions to a problem. For example, a qubit may be considered a noise-susceptible device or device that is susceptible to noise because noise on the qubits may interfere with properly annealing the quantum processor and/or can lead to a different problem being solved. Note that the phrase “noise-susceptible” or “susceptible to noise” does not necessarily suggest that the device itself is physically more or less sensitive to noise compared to other devices that are not described as noise-susceptible. Sensitivities to processor performance is higher in noise-susceptible devices relative to devices that are described as less susceptible to noise.

Noise in a quantum processor may cause qubits to decohere which reduces the efficacy of tunneling. As a result, processor performance may be diminished, and solutions generated from the processor may be suboptimal. Existing approaches for improving coherence include adding circuitry to shield qubits or making significant modifications to processor layouts which, in some cases, may be impractical. The present disclosure describes an advantageous approach in which coherence may be improved in a quantum processor while maintaining a streamlined processor layout.

Performance of a superconducting processor may be easily affected by the performance of certain superconducting devices that are susceptible to noise, for example, qubits and couplers. Since processor performance is particularly sensitive to proper or improper operation of these devices, it is desirable to reduce noise in these devices as much as possible. For a superconducting processor, one of the dominant sources of environmental noise is flux noise. Flux noise may cause decoherence which induces a transition from coherent to incoherent tunneling before the transition is induced by intrinsic phase transitions. Device decoherence during computation may limit the speed and/or accuracy with which the processor evolves and produces solutions. Additionally, flux noise may increase spin bath susceptibility which is a “memory” effect that results in diminished sampling and optimization performance. Systems and methods to reduce spin bath polarization are described in US Patent Publication No. 2019-0019099 A1.

One approach to reducing the effect of flux noise is to use a low-noise material for regions of an integrated circuit that include superconducting devices for which reducing noise is particularly advantageous. This may include using a low-noise material, such as aluminum, for wiring regions that comprise one or more wiring layers that form analog circuitry that contains, for example, qubits and couplers. A different superconducting material, such as niobium, may be used for regions of an integrated circuit that comprise one or more wiring layers that include superconducting devices for which noise reduction is desired but not as advantageous. Such layers may include, for example, part or all of one or more digital-to-analog converters (DACs). Thus, it may be beneficial for a superconducting integrated circuit to have noise-susceptible superconducting devices that comprise a low-noise material and other superconducting devices that comprise a different superconducting material.

The two superconducting materials will transition into superconductivity at their respective critical temperatures. Critical temperature is an intrinsic property of a superconducting material and is the temperature at which the electrical resistance of the superconducting material drops to zero (i.e., temperature at which the material becomes superconductive). At and below the critical temperature, two electrons in a wire comprising the superconducting material will form a Cooper pair and current persists without additional energy. For example, the critical temperatures of aluminum and niobium are approximately 1.2 Kelvin and 9.3 Kelvin, respectively. At and below these respective critical temperatures, aluminum and niobium wires have zero electrical resistance. Superconductivity is indicative of a quantum mechanical state and may therefore be useful in fabricating a superconducting integrated circuit such as a quantum processor.

For a superconducting integrated circuit that includes wiring regions comprising more than one material, the ordering and arrangement of the different materials may impact the functionality of the superconducting integrated circuit, and thus processor performance. In particular, the ordering and arrangement of the different materials may impact the noise characteristics of the processor. The impact of noise on the processor is discussed in further detail above. Notably, it may be desirable to have the wiring regions arranged in a sequence that is beneficial for coherent operation. More specifically, a processor may be ordered so that noise-susceptible superconducting devices, such as qubits, are positioned in low-noise wiring regions that are below wiring regions that may be formed from non-low-noise materials. Such an arrangement reduces or prevents exposure of noise-susceptible superconducting devices to non-low-noise materials and thus to a potential source of decoherence.

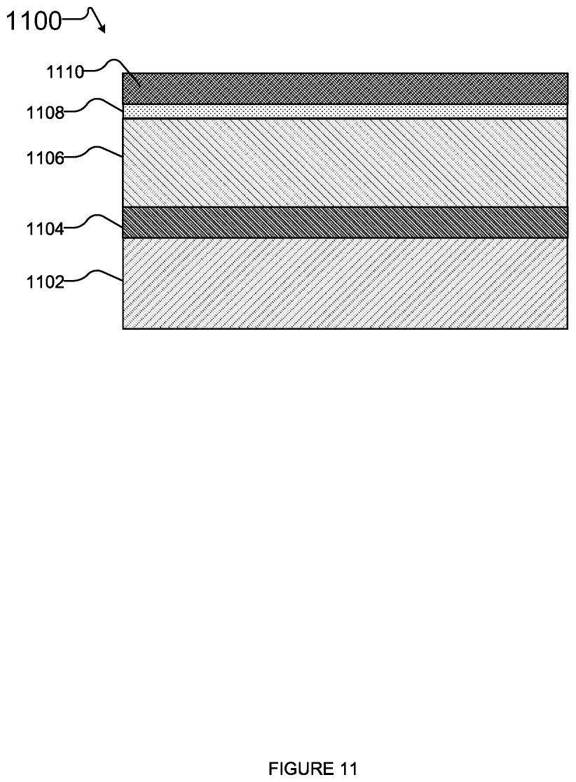

FIG. 11 is a sectional view of a portion of an example superconducting integrated circuit 1100 comprising superconductive wiring regions arranged for improved coherence, in accordance with the present articles and methods.

Integrated circuit 1100 includes a first superconductive wiring region 1102. First superconductive wiring region 1102 may comprise one or more superconductive wiring layers, each comprising a low-noise material. In some implementations, first superconductive wiring region 1102 comprises aluminum. In some implementations, first superconductive wiring region 1102 is carried by an electrically insulating layer or substrate (not shown in FIG. 11).

A second superconductive wiring region 1104 overlies first superconductive wiring region 1102. Second superconductive wiring region 1104 may comprise one or more superconductive wiring layers, each comprising a low-noise material. In some implementations, second superconductive wiring region 1104 comprises aluminum.

As used herein, overlie refers to a layer either directly or indirectly overlying a referenced layer. Directly overlying a referenced layer refers to the layer being formed directly on at least a portion of the referenced layer without an intervening layer. Indirectly overlying a layer refers to the layer being formed over at least a portion of the referenced layer, with at least one intervening layer between the referenced layer and the layer. Second superconductive wiring region 1104 may be placed either directly on first superconductive wiring region 1102 or may have intervening layers between first superconductive wiring region 1102 and second superconductive wiring region 1104. For example, in the implementation of FIG. 11, intervening layers such as shielding layers or dielectric layers may be placed between superconductive wiring layers.

First and second superconductive wiring regions 1102 and 1104 may comprise at least a portion of at least one noise-susceptible superconducting device, including at least one of: a qubit and a coupler. In some implementations, the qubit may be a superconducting flux qubit, comprising a loop of a low-noise material interrupted by at least one Josephson junction. In some implementations, the coupler may similarly comprise a loop of a low-noise material interrupted by at least one Josephson junction.

A third superconductive wiring region 1106 overlies second superconductive wiring region 1104. Third superconductive wiring region 1106 may comprise one or more superconductive wiring layers, each comprising a material that is superconductive in a respective range of temperatures. In one implementation, third superconductive wiring region 1106 may comprise niobium.

An optional kinetic inductance region 1108 may overlie third superconductive wiring region 1106. In one implementation, kinetic inductance region 1108 may be integrated into third superconductive wiring region 1106 (not illustrated in FIG. 11).

Kinetic inductance region 1108 comprises a layer of material that is superconductive in a respective range of temperatures. High kinetic inductance material as used herein refers to a material for which the kinetic portion of the inductance is larger than the magnetic portion of the inductance. In one implementation, kinetic inductance region 1108 may comprise titanium nitride. In another implementation, kinetic inductance region 1108 may comprise niobium nitride.

A fourth superconductive wiring region 1110 overlies third superconductive wiring region 1106. Fourth superconductive wiring region 1110 may also optionally overlie kinetic inductance region 1108, as illustrated in FIG. 11. Fourth superconductive wiring region 1110 may comprise one or more superconductive wiring layers, each comprising a material that is superconductive in a respective range of temperatures. In one implementation, fourth superconductive wiring region 1110 may comprise niobium.

The superconductive material of fourth superconductive wiring region 1110 may form at least a portion of at least one digital-to-analog converter (DAC). The DAC may comprise a loop of superconducting material interrupted by at least one Josephson junction.

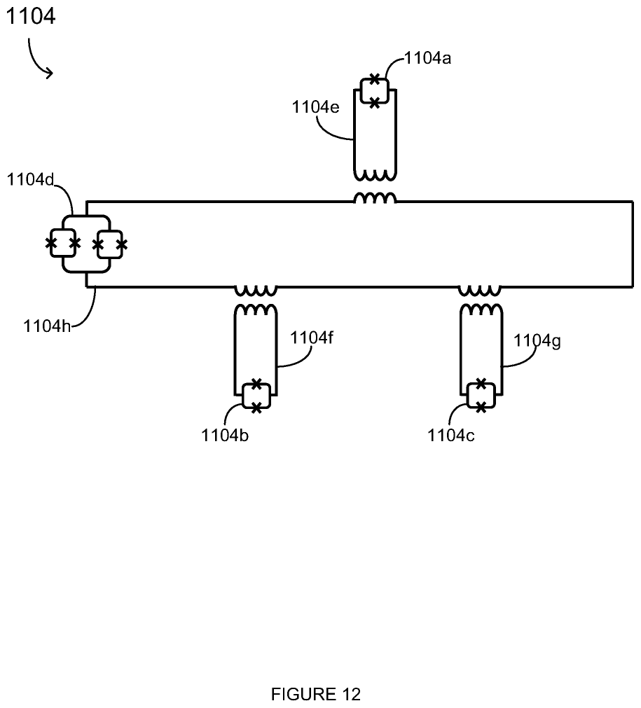

FIG. 12 is a schematic diagram that illustrates an example portion of second superconductive wiring region 1104, according to one implementation of the present disclosure. The exemplary portion of second superconductive wiring region 1104 shown in FIG. 12 comprises noise-susceptible superconducting devices, including a coupler 1104h and three superconducting flux qubits 1104e, 1104f and 1104g.

Coupler 1104h and qubits 1104e, 1104f and 1014g each include a body that forms a loop. The bodies are made from one or more superconductive low-noise materials, such as aluminum. In the example implementation shown in FIG. 12, coupler 1104h includes a compound Joseph junction (CJJ) 1104d as described in U.S. Pat. No. 8,536,566. CJJ 1104d comprises a primary CJJ structure, the primary CJJ structure comprising a pair of parallel current paths, each of which is interrupted by a respective secondary CJJ structure. In some implementations, CJJ 1104d comprises a single CJJ structure. FIG. 12 further illustrates qubits 1104e, 1104f and 1104g comprising respective CJJs 1104a, 1104b and 1104c.

As aforementioned, it is beneficial to processor performance that low-noise wiring regions comprising noise-susceptible superconducting devices be located below wiring regions comprising non-low-noise material, an example implementation of which is depicted in FIG. 11. Ordering the wiring regions in such a sequence reduces or prevents low-noise wiring (e.g., wiring comprising a material such as aluminum) from being exposed to relatively higher-noise wiring (e.g., wiring comprising a material such as niobium). It follows that such an arrangement also reduces or prevents exposure of noise-susceptible superconducting devices to relatively higher-noise material (e.g., niobium), which allows for higher coherence and thus enhanced processor performance.

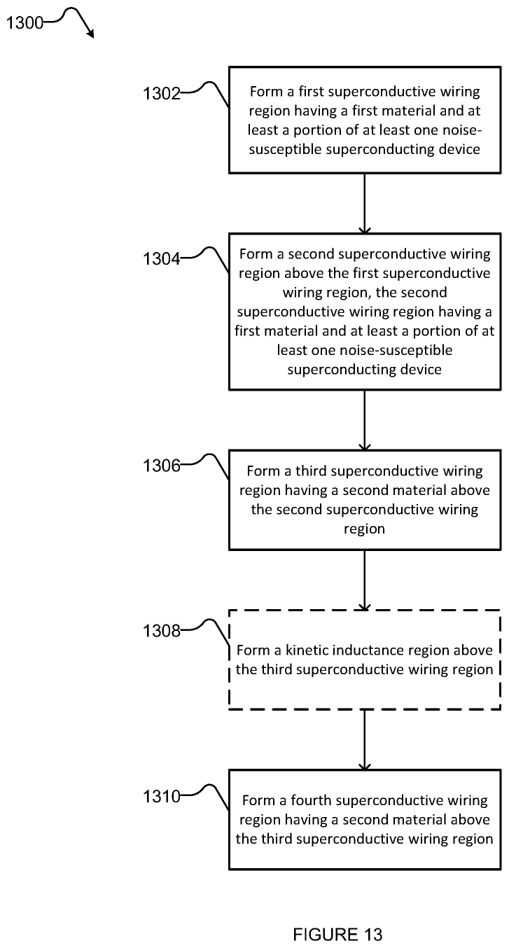

FIG. 13 is a flowchart that illustrates an example method 1300 of fabricating a portion of a superconducting integrated circuit comprising superconductive wiring regions arranged for improved coherence, in accordance with the present articles and methods. Method 1300 includes acts 1302-1310, though in other implementations, certain acts may be omitted and/or additional acts may be added. Method 1300 may be performed by, for example, integrated circuit fabrication equipment in response to an initiation of a fabrication process.

At 1302, a first superconductive wiring region having a first type of material is formed. The first type of material is a low-noise material that is superconductive in a first range of temperatures. Forming the first superconductive wiring region includes forming one or more wiring layers from the first type of material. In some implementations, the first type of material is aluminum. Forming the first superconductive wiring region may, for example, include depositing, planarizing and/or etching one or more layers of the first superconductive wiring region.

At 1304, a second superconductive wiring region having the first type of material is formed to overlie the first superconductive wiring region. Forming the second superconductive wiring region may include forming one or more wiring layers from the first type of material. Forming the second superconductive wiring region may, for example, include depositing, planarizing and/or etching one or more layers of the second superconductive wiring region. Forming the first and second superconductive wiring regions, acts 1302 and 3104, comprises forming at least a portion of at least one noise-susceptible superconducting device. In one implementation, forming at least one noise-susceptible device comprises forming at least one of: a qubit and a coupler.

At 1306, a third superconductive wiring region having a second type of material is formed to overlie the second superconductive wiring region. Forming the third superconductive wiring region may include forming one or more wiring layers from a second type of material. The second type of material is superconductive in a second range of temperatures. In one implementation, the second type of material is niobium. Forming the third superconductive wiring region may, for example, include depositing, planarizing and/or etching one or more layers of the third superconductive wiring region.

Optionally, at 1308, a kinetic inductance region is formed to overlie the third superconductive wiring region. In some implementations, a kinetic inductance region is formed within the third superconductive wiring region. Forming the kinetic inductance region may, for example, include depositing, planarizing and/or etching one or more layers of the kinetic inductance region.

Forming the kinetic inductance region comprises forming a layer of material that causes a larger proportion of current energy stored in the kinetic inductance region to be stored as kinetic energy than magnetic energy, the material being superconductive in a respective range of temperatures. In one implementation, the high kinetic inductance material is titanium nitride. In another implementation, the high kinetic inductance material is niobium nitride.

At 1310, a fourth superconductive wiring region having the second type of material is formed to overlie the third superconductive wiring region. Forming the fourth superconductive wiring region may include forming one or more wiring layers from the second type of material. Forming the fourth superconductive wiring region may further comprise forming at least one digital-to-analog converter (DAC). Forming the fourth superconductive wiring region may, for example, include depositing, planarizing and/or etching one or more layers of the fourth superconductive wiring region.

### Digital to Analog Converters (DACs)

As discussed above with respect to the example circuit 200a of FIG. 2A, a quantum processors provide a plurality of controllable devices for performing computations with quantum effects. Controllable devices include qubits, couplers (which couple qubits, also referred to herein as qubit couplers), and components thereof. Controllable devices are controlled via signals applied to influence their operation—for example, a biasing signal may be applied to a flux qubit to affect its flux during computation. These signals may be provided by programmable devices such as DACs.

Such signals often require conversion and/or storage prior to being applied to controllable devices. For example, a classical computer may generate digital signals for the quantum processor, and those digital signals may be converted to analog form via one or more digital-to-analog converters (DACs). The converted analog signal may then be applied to the controllable device. As another example, a signal (which may be digital or analog) may be received by the quantum processor at one time before or during a computation and stored via a DAC until the signal is to be applied to a controllable device at a later time. DACs may be used for one or more of these purposes (i.e., conversion and/or memory) and/or for other purposes including storage, programming, and readout within a quantum processor. Examples of applications of DACs for these and other purposes are described in greater detail in, for example, U.S. Pat. Nos. 7,876,248 and 8,098,179. The operation of Josephson junctions (JJs) and/or compound Josephson junctions (CJJs) in DACs is described in greater detail in, for example, U.S. Pat. Nos. 7,876,248 and 8,098,179, U.S. Patent Application Publication No. 2018/0101786, and U.S. Pat. No. 11,127,893.

Superconducting quantum processors often comprise a plurality of DACs for these and other functions. Such DACs include superconducting DACs which store a flux (sometimes referred to as ϕ-DACs), which generally comprise a storage inductor (e.g., a superconducting magnetic coil) and a programmable coupling element. ϕ-DACs take advantage of the flux rate of change of the circuit (e.g., of the storage inductor) to store energy in their magnetic fields, thereby generating an effective inductance (sometimes referred to as a magnetic inductance).

ϕ-DAC designs may impose various costs on the design of the processor. For example, magnetic storage inductors which can store sufficient flux for a typical design are often relatively large (and may require several fabrication layers using current techniques), which may constrain the space available for other components on the processor. Further, the magnetic field generated by the ϕ-DAC may be powerful and require significant shielding. Even when shielded, the ϕ-DAC will likely result in cross-talk with other flux-sensitive devices on the processor. Further still, at least some ϕ-DAC designs are particularly sensitive to fabrication variability. Examples of ϕ-DAC designs are described in greater detail in, for example, Johnson et al., “A scalable control system for a superconducting adiabatic quantum optimization processor”, arXiv:0907.3757; and Bunyk et al., “Architectural considerations in the design of a superconducting quantum annealing processor”, arXiv:1401.5504.

Although the term DAC is used throughout, it will be understood that the described devices may be used for a variety of purposes which are not necessarily restricted to converting digital signals to analog signals (and, in some implementations, do not involve such conversion at all). For example, as described above, superconducting DACs may be used by quantum processors to store a signal for a period of time (e.g., thereby operating as a form of memory).

### Kinetic Inductance

Current flowing through a metal material in principle stores energy both in the magnetic field of that metal and in the kinetic energy of the charge carriers (e.g., the electrons or Cooper pairs). In non-superconducting metals, the charge carriers collide frequently with the lattice and lose their kinetic energy as Joule heating. This is also referred to as scattering, and quickly releases energy. However, in superconducting materials, scattering is substantially reduced, as the charge carriers are Cooper pairs which are protected against dissipation through scattering. This allows for superconducting materials to store energy in the form of kinetic inductance. This phenomenon allows kinetic inductance to efficiently store energy within the superconducting metal. Kinetic inductance is at least in part determined by the inertial mass of the charge carriers of a given material and increases as carrier density decreases. As the carrier density decreases, a smaller number of carriers must have a proportionally greater velocity in order to produce the same current. Materials that have high kinetic inductance for a given area (as defined below) are referred to as “kinetic inductance materials”, or “high kinetic inductance materials”.

Kinetic inductance materials are those that have a high normal-state resistivity and/or a small superconducting energy gap, resulting in a larger kinetic inductance per unit of area. In general, total inductance L of a superconducting material is given by L=L_{K} L_{G}, where L_{G} is the geometric inductance and L K is the kinetic inductance. The kinetic inductance of a superconducting film in near-zero temperatures is proportional to the effective penetration depth λ_{eff}. In particular, for a film with a given thickness t, the kinetic inductance of the film is proportional to the ratio of the width of the film W to the length of the film L, where length is in the direction of the current and width is orthogonal to length (note that both width and length are orthogonal to the dimension in which thickness is measured). That is,

$${L}_{K} ∼ {λ}_{eff} \frac{L}{W}$$

for a superconducting film with a given thickness. The kinetic inductance fraction of a material is characterized as α=Lₖ/(L_{g}+Lₖ). A material considered to have high kinetic inductance would typically have a in the range of 0.1<α≤1. Materials with less than 10% of the energy stored as kinetic inductance would be considered traditional magnetic storage inductors with a small correction.

In some implementations it may be beneficial to attempt to maximize kinetic inductance in minimal volume. This may include attempting to minimize the width of the film, selecting a suitable material with a high effective penetration depth λ_{eff}, and selecting a length for the film which achieves the desired kinetic inductance. It may also be beneficial to attempt to minimize the thickness t of the material, subject to fabrication constraints, as for t<3λ_{eff}(bulk) (where λ_{eff}(bulk) is the effective penetration depth of the material in bulk, not thin-film), λ_{eff} increases at least approximately proportionately to 1/t². In some implementations, t<n·λ_{eff}(bulk), where n is some value substantially less than 1 (e.g., 0.5, 0.1, 0.05, 0.01, etc.).

A high kinetic inductance material as discussed herein is also a superconducting material that experiences a transition to superconducting behavior at a critical temperature T_{c}. Above T_{c}, the material is non-superconducting, while below T_{c} the material behaves as a superconductor. The critical temperature is also referred to in the present application as the transition temperature. As discussed above, a high kinetic inductance material may be defined as one where at least 10% of the energy stored in the high kinetic inductance material is stored as kinetic inductance, or where the kinetic inductance fraction of the high kinetic inductance material is 0.1<α≤1. In some implementations, the single layer of high kinetic inductance material may be one of WSi, MoN, NbN, NbTiN, TiN, and granular Aluminum, and may be substantially planar. For example, in some implementations high kinetic inductance material may be deposited by electron beam lithography or vacuum evaporation and may have a thickness of 20-50 nm and a line width of 130 nm. Material may also be deposited by a sputtering process, or by other deposition processes. The dimensions of the devices will be determined by the selected deposition process, and may, in some implementations, be set by the etch or liftoff process used to pattern the layer. In some implementations, for example, where lithography is used, the dimensions may be selected from as small as a few nanometers to larger than a few microns. In addition, the thickness of the layer may be varied between as small as a few nanometers to thicker than a few hundred nanometers.

### Example Superconducting Integrated Circuits

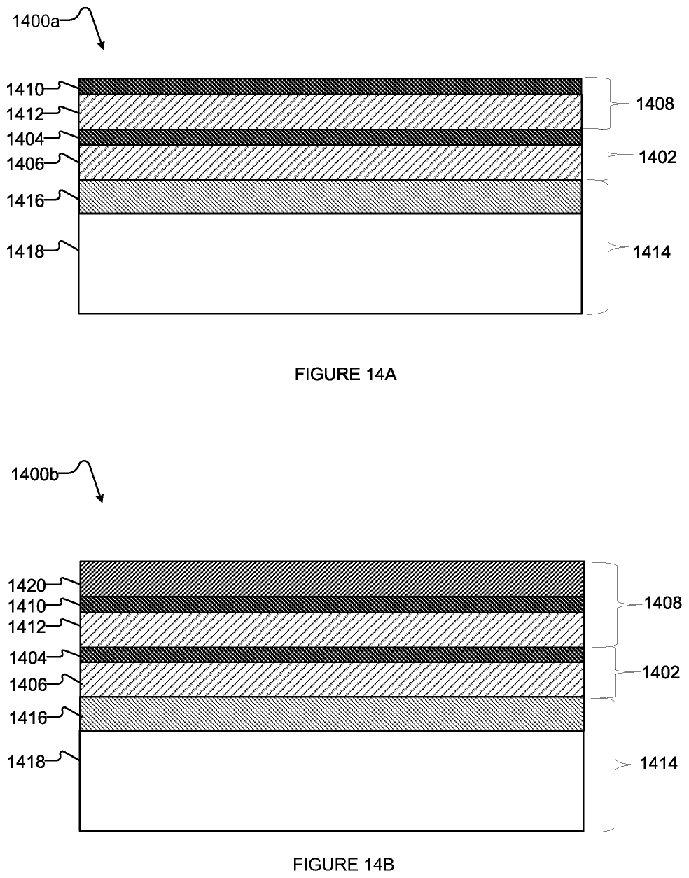

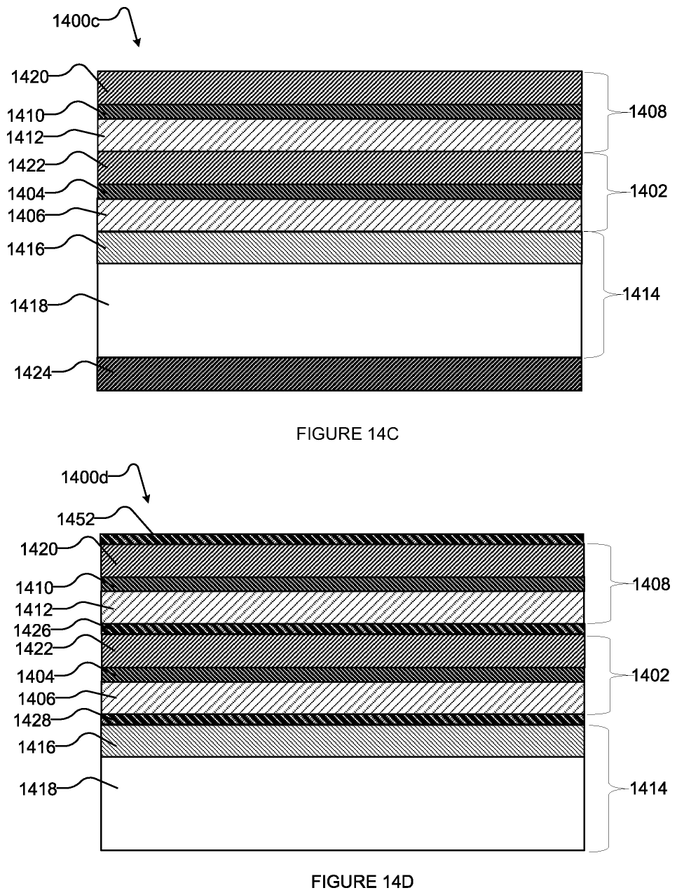

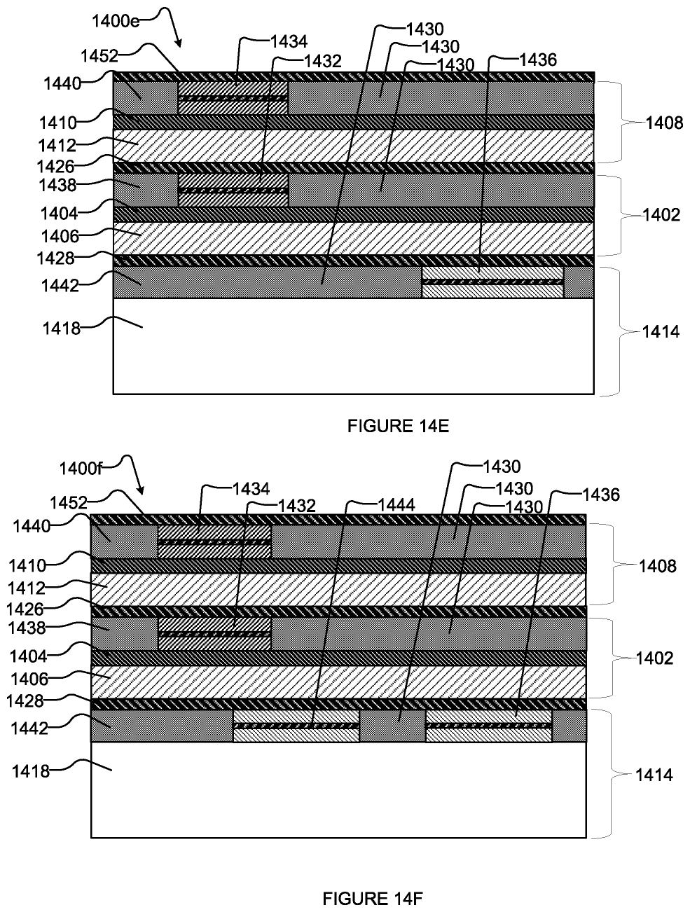

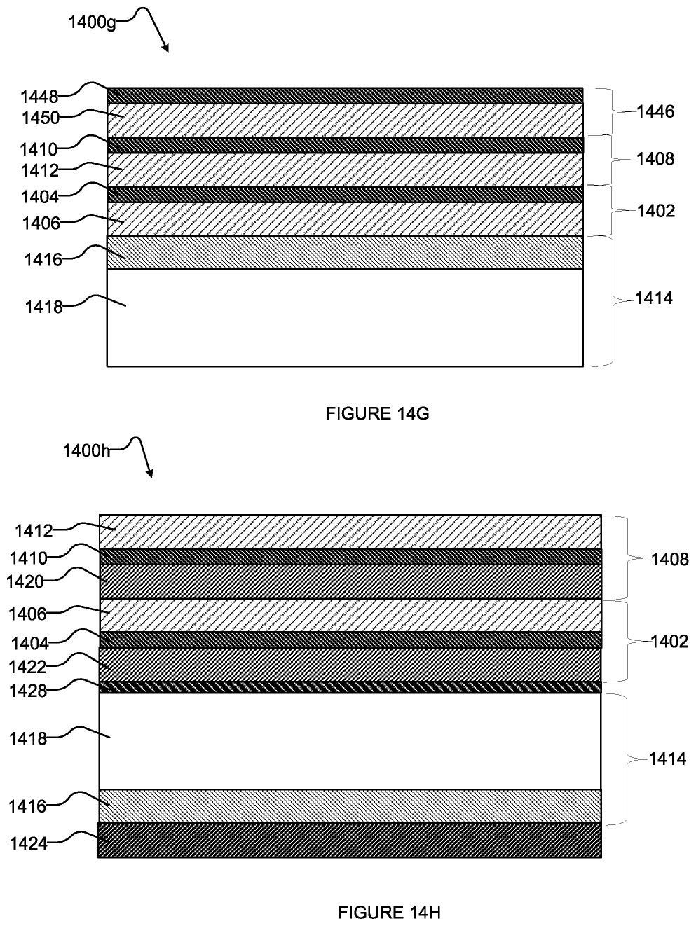

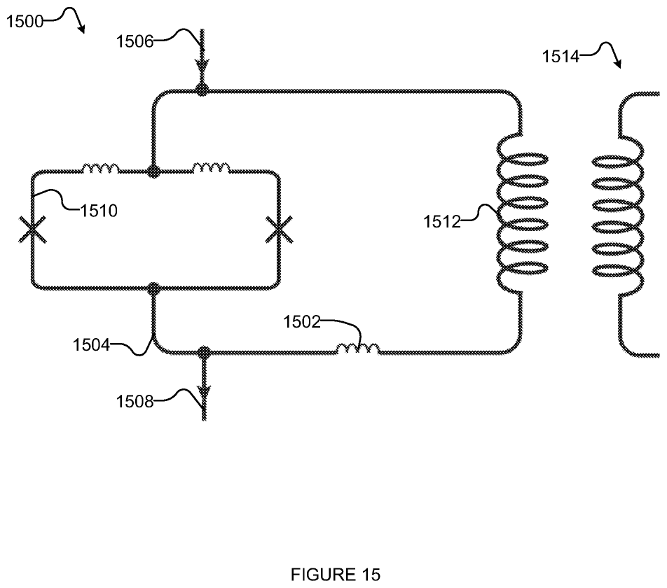

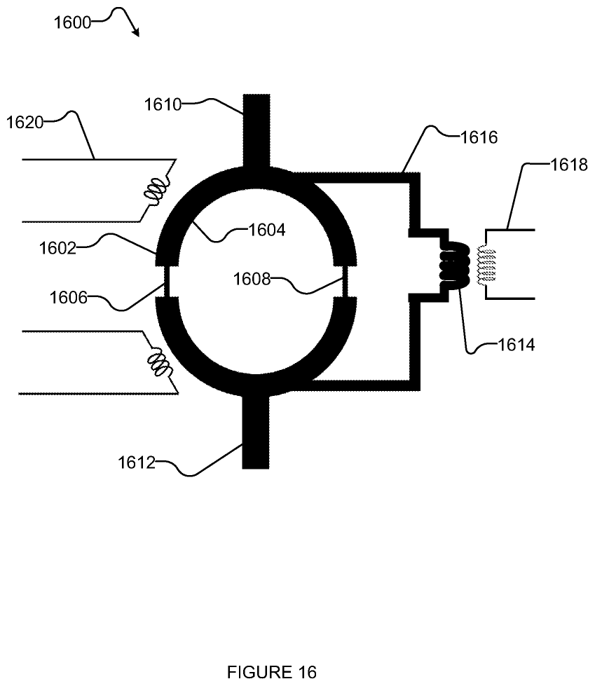

Referring to FIG. 14A, superconducting integrated circuit 1400a is shown. A first stack 1402 has a first superconducting wiring layer 1404 formed from a first high kinetic inductance material and a second superconducting wiring layer 1406 communicatively coupled to first superconducting wiring layer 1404 to form a first control circuit. Examples of control circuits are discussed in further detail below with respect to FIGS. 15 and 16. A second stack 1408 has a third superconducting wiring layer 1410 formed from a second high kinetic inductance material and a fourth superconducting wiring layer 1412 communicatively coupled to third superconducting wiring layer 1410 to form a second control circuit. In some implementations, the first control circuit and the second control circuit each comprise a digital to analog converter (DAC). As used herein, communicatively coupled includes galvanic, capacitive, and inductive coupling between components. Second superconducting wiring layer 1406 and fourth superconducting wiring layer 1412 may include multiple layers, such as layers of wiring and vias deposited in electrical connection and surrounded by dielectric. Second stack 1408 overlies first stack 1402. As used herein, overlie refers to a layer either directly or indirectly overlying a referenced layer. Directly overlying a referenced layer refers to the layer being formed directly on at least a portion of the referenced layer without an intervening layer. Indirectly overlying a layer refers to the layer being formed over at least a portion of the referenced layer, with at least one intervening layer between the referenced layer and the layer. Second stack 1408 may be placed either directly on first stack 1402 or may have intervening layers between first stack 1402 and second stack 1408. It will be understood that stacks 1402 and 1408 may contain other devices, such as readout resonators, in addition to control circuits such as DACs.

Second superconducting wiring layer 1406 and fourth superconducting wiring layer 1412 may, for example, be niobium or aluminum. In some implementations, layers 1406 and 1412 may contain body loops or control circuitry. A third stack 1414 contains a controllable device. Examples of controllable devices include qubits, couplers, parameter tuning devices, and readout devices and are discussed in further detail above with respect to FIG. 2B. In some implementations, the controllable device is one of a qubit or a coupler. In some implementations the controllable device may be a readout device or a parameter tuning device for a qubit or a coupler. For example, a parameter tuning device for a qubit may include devices that tune qubit capacitance or inductance, as described in U.S. Pat. No. 8,536,566, or persistent current compensators, as described in U.S. Pat. No. 9,015,215. It will be understood that these are examples of qubit parameter tuning devices, and other devices that influence qubit or coupler properties may also be included. These devices may, for example, be used in calibration of the processor. In some implementations, third stack 1414 has multiple controllable devices, such as multiple qubits that are coupled by couplers. In the example implementation of FIG. 14A, third stack 1414 has two layers, 1416 and 1418. In some implementations the third stack has multiple layers and may have layers in addition to the two shown as forming third stack 1414 in the example implementations shown. In some implementations, layer 1416 may contain Josephson junctions, such as qubit or coupler Josephson junctions, while layer 1418 may contain superconducting loops or other wiring to form qubits or couplers in combination with the Josephson junctions. It will be understood that layer 1418 may include multiple layers and devices. It will also be understood that layer 1416 and layer 1418 may also form readout devices or parameter tuning devices for the qubits or couplers. In some implementations it may be beneficial to have wiring layer 1416 overlie wiring layer 1418, such as, for example, where wiring layer 1418 has multiple wiring layers and the formation of wiring layer 1418 includes processing that may be damaging to trilayer Josephson junctions formed in wiring layer 1416 (e.g., high temperature deposition).

At least one of the first control circuit and the second control circuit is communicatively coupled to the controllable device. As discussed with reference to FIG. 15 and FIG. 16, the first control circuit and/or the second control circuit may be DACs. A DAC may be considered to have three primary components, the first being the source, provided by the Josephson junction (1510 in FIG. 15, 1604 in FIG. 16), a storage inductor (1502 in FIG. 15, 1616 in FIG. 16), and an output transformer or control coupler (1512 in FIG. 15, 1614 in FIG. 16). It will be understood that while the control circuits are described as being formed in first and second stacks 1402 and 1408, and the controllable devices are described as being formed in third stack 1414, some component of these devices may traverse other layers to provide the communicative coupling. For example, the output transformer or control coupler (also referred to herein as “control coupler wiring”) of the DAC (1512 in FIG. 15, 1614 in FIG. 16) may extend into wiring layers 1416 and/or 1418 to communicatively couple with the respective controllable device, such as by inductive or galvanic coupling. In other examples, a component of the controllable device, such as the coupling portions shown as 1414 in FIGS. 15 and 1618 shown in FIG. 16, (also referred to herein as “controllable coupler wiring”) may extend into one or more of wiring layers 1404, 1406, 1410, and 1412 in order to couple with the control coupler of the DAC, such as by inductive or galvanic coupling. Thus, while the DAC or the controllable device is described as being formed in a particular stack, it will be understood that a portion of the DAC or controllable device may be formed in another stack to enable coupling. Coupling wiring may extend from either the DAC or the controllable device, and may, for example, be formed by a series of vias passing through respective layers to reach the coupling location.

In some implementations, first stack 1402 and second stack 1408 overlie third stack 1414. As used herein, the term “stack” refers to a subset of the layers of superconducting integrated circuit 1400a. The layers within the stack are adjacent and may have varying numbers of layers and ordering of the layers within the stack. In some implementations, first superconducting wiring layer 1404 and third superconducting wiring layer 1410 are the top layer of their respective stacks. In some implementations, first stack 1402, second stack 1408, and third stack 1414 overlie a substrate (shown in FIG. 14C). In other implementations, first stack 1402, second stack 1408, and third stack 1414 may overlie other components of a circuit, such as other layers and devices.

In some implementations, the first high kinetic inductance material and the second high kinetic inductance material may be the same, which may include having the same chemical composition and the same material properties. The first and second high kinetic inductance materials may have at least 10% of the energy stored in the respective high kinetic inductance material stored as kinetic inductance, may have respective kinetic inductance fractions of 0.1<α≤1, and may be one of WSi, MoN, NbN, NbTiN, TiN, and granular Aluminum.

In the example implementation of FIG. 14B, superconducting integrated circuit 1400b has a third stack 1414 with layers 1416 and 1418. Overlying third stack 1414 is first stack 1402, having high kinetic inductance layer 1404, and wiring layer 1406. Overlying first stack 1402 is second stack 1408, having high kinetic inductance layer 1410, wiring layer 1412, and wiring layer 1420.

In the example implementation of FIG. 14C, superconducting integrated circuit 1400c has a third stack 1414 with layers 1416 and 1418. Overlying third stack 1414 is first stack 1402, having high kinetic inductance layer 1404, and wiring layers 1406 and 1422. Overlying first stack 1402 is second stack 1408, having high kinetic inductance layer 1410, wiring layer 1412, and wiring layer 1420. All of the layers overlie substrate 1424. Substrate 1424 may be formed of silicon, sapphire, quartz, silicon dioxide, or any other suitable material. It will be understood that substrate 1424 may support any of the integrated circuits 1400a-1400g described herein.

In some implementations, the ordering of the stacks may be determined by the noise susceptibility of the devices formed in the layers of the respective stack. For example, in some implementations, the first control circuit and the second control circuit may have low susceptibility to noise. The devices in these stacks may include DACs. Further, the controllable device may have high susceptibility to noise. These devices may include qubits and couplers. In some implementations, third stack 1414 may contain controllable devices that have a high susceptibility to noise, which may be formed from low noise materials such as low noise dielectrics and superconducting materials such as Aluminum. The devices with a high susceptibility to noise may be placed on the lower layers of the superconducting integrated circuit to further reduce noise. In addition, shielding layers may be included to reduce crosstalk and other noise between layers.

In the present specification, the phrase “noise-susceptible superconducting device” or “device having high susceptibility to noise” is used to describe a superconducting device that is susceptible to noise and for which a noise-free operating environment is highly desirable for performance of a superconducting integrated circuit, for example, a quantum processor. Poor performance of a noise-susceptible device may result in the quantum processor producing an inaccurate or suboptimal solution to a problem, for example, an inaccurate or suboptimal result of quantum annealing. Note that the phrases “noise-susceptible” and “susceptible to noise” do not necessarily suggest that the device itself is physically more or less sensitive to noise compared to other devices that are not described as noise-susceptible. Instead, “noise-susceptible” is used to refer to the sensitivity of processor performance to noise within a given device. The sensitivity of the processor performance to noise is higher in noise-susceptible devices than in devices that are described as less susceptible to noise or as “devices having low susceptibility to noise”. Sources of noise in a quantum processor may, for example, include, but are not limited to, flux noise, charge noise, magnetic fields, and high frequency photons.

In the example implementation of FIG. 14D, superconducting integrated circuit 1400d has a third stack 1414 with layers 1416 and 1418. Overlying third stack 1414 is first stack 1402, having high kinetic inductance layer 1404, and wiring layers 1406 and 1422. Overlying first stack 1402 is second stack 1408, having high kinetic inductance layer 1410, wiring layer 1412, and wiring layer 1420. In some implementations, such as the implementation of FIG. 14D, a superconducting shielding layer 1426 may separate first stack 1402 from second stack 1408. Similarly, a superconducting shielding layer 1428 may separate first stack 1402 and second stack 1408 from third stack 1414. Optionally, a superconducting shielding layer 1452 may overlay second stack 1408. In another implementation, as shown in FIG. 14H, a superconducting shielding layer 1428 may separate first stack 1402 from third stack 1414, without the need for superconducting shielding layer 1426. In other implementations, shielding layers may be included between any layer as needed by the particular application. It will be understood that while superconducting shielding layers are shown as discrete layers in the Figures, the superconducting shielding layer may be formed from the material of wiring layers 1406 and 1412. In some implementations, wiring layers 1406 and 1412 may be Niobium, and superconducting shielding layer 1426, 1428 or 1452 may be a layer of Niobium.

In the example implementation of FIG. 14E, superconducting integrated circuit 1400e has a third stack 1414 with layer 1418. Overlying third stack 1414 is first stack 1402, having high kinetic inductance layer 1404 and wiring layer 1406. Overlying first stack 1402 is second stack 1408, having high kinetic inductance layer 1410 and wiring layer 1412. Superconducting shielding layer 1426 separates first stack 1402 from second stack 1408, and superconducting shielding layer 1428 separates first stack 1402 and second stack 1408 from third stack 1414. Optionally, superconducting shielding layer 1452 may overlay second stack 1408. First stack 1402 includes Josephson junction layer 1438, with areas of dielectric 1430, and a trilayer Josephson junction 1432. Second stack 1408 includes Josephson junction layer 1440, with areas of dielectric 1430, and a trilayer Josephson junction 1434. Third stack 1414 includes a Josephson junction layer 1442 with areas of dielectric 1430 and a trilayer Josephson junction 1436. In other implementations only one stack may have a Josephson junction layer with trilayer Josephson junctions. In other implementations, one or more Josephson junction layers may have multiple trilayer Josephson junctions. See, for example, FIG. 14F, discussed in further detail below. In the example implementation of FIG. 14E, each Josephson junction layer is formed in the top layer of the respective stack.

It will be understood that the trilayer Josephson junctions shown in FIGS. 14E and 14F are representative structures only, and that an implementation of any superconducting integrated circuit would involve additional detail, such as, for example, wiring (e.g., electrically conductive traces) connected to both sides of the Josephson junction and leading to a body loop or other components. It will also be understood that the Josephson junctions may not be the full height of the respective layer, and that one or more additional wiring layers may be included within the layer, such as layers 1438, 1440, and 1442. Further details on implementations of circuits with Josephson junctions are described in, for example, U.S. Pat. Nos. 7,533,068; 8,008,942; 8,195,596; 8,190,548; and 8,421,053.

In the example implementation of FIG. 14F, superconducting integrated circuit 1400f has a third stack 1414 with layers 1442 and 1418. Overlying third stack 1414 is first stack 1402, having high kinetic inductance layer 1404, wiring layer 1406, and Josephson junction layer 1438. Overlying first stack 1402 is second stack 1408, having high kinetic inductance layer 1410, wiring layer 1412, and Josephson junction layer 1440. Superconducting shielding layer 1426 separates first stack 1402 from second stack 1408, and superconducting shielding layer 1428 separates first stack 1402 and second stack 1408 from third stack 1414. Optionally, superconducting shielding layer 1452 may overlay second stack 1408. The respective stacks include areas of dielectric 1430, and trilayer Josephson junctions 1432, 1434, and 1436. Josephson junction layer 1442 also includes a second trilayer Josephson junction 1444.

In other implementations, Josephson junctions may be formed directly within a layer of high kinetic inductance material, such as wiring layers 1404 and 1410. Referring to the example implementation of FIG. 14A, at least one of first superconducting wiring layer 1404 and third superconducting wiring layer 1410 may include a Josephson junction formed from the respective high kinetic inductance material. In some implementations, each of wiring layers 1404 and 1410 includes a Josephson junction formed from the respective high kinetic inductance material. Josephson junctions may be formed in high kinetic inductance material by the creation of restrictions. This is discussed further below with respect to FIG. 16, as well as in International Patent Publication No. WO2021/231224A1.

In the example implementation of FIG. 14G, superconducting integrated circuit 1400g has a third stack 1414 with layers 1416 and 1418. Overlying third stack 1414 is first stack 1402, having high kinetic inductance layer 1404 and wiring layer 1406. Overlying first stack 1402 is second stack 1408, having high kinetic inductance layer 1410 and wiring layer 1412. Superconducting integrated circuit 1400g has a fourth stack 1446 with a fifth superconducting wiring layer 1448 and a sixth superconducting wiring layer 1450. Fifth superconducting wiring layer 1448 is formed from a third high kinetic inductance material, having properties as discussed above. Fifth superconducting wiring layer 1448 and sixth superconducting wiring layer 1450 are communicatively coupled to form a third control circuit. Fourth stack 1446 overlies first stack 1402 and second stack 1408.

It will be understood that the order of layers within stacks 1402, 1408, and 1414 may be varied. In the example implementation of FIG. 14H, superconducting integrated circuit 1400h has first stack 1402 with high kinetic inductance layer 1404 and wiring layer 1406 overlying wiring layer 1422, and second stack 1408 having high kinetic inductance layer 1410 and wiring layer 1412 overlying wiring layer 1420. First stack 1402 and second stack 1408 are separated from third stack 1414 by superconducting shielding layer 1428. Third stack 1414 has layer 1418 overlying layer 1416, and third stack 1414 overlies a substrate 1424. As discussed above, it will be understood that the individual layers called out within each stack may be formed from multiple layers of material. In some implementations, it may be beneficial to place high kinetic inductance layers 1404 and 1410 adjacent to wiring layers 1420 and 1422. For example, where wiring layers 1420 and 1422 contain trilayer Josephson junctions, it may be beneficial to place high kinetic inductance layers 1404 and 1410 adjacent to the trilayer Josephson junction layer.

FIGS. 14A through 14H are example implementations of superconducting integrated circuits having at least two control circuits that are vertically stacked. This may also be referred to as two control circuits contained within the footprint used for one of the control circuits. This may allow for a reduction in size of a quantum processor. In some implementations, reducing the horizontal size, or area, of a quantum processor may allow for controllable devices, such as qubits and couplers, to have shorter wiring loops. This may beneficially allow for a quantum processor to operate at a higher energy scale. Reducing the overall footprint, or horizontal area, of the processor that contains the control circuits, also referred to herein as control circuitry may also allow for greater freedom in the design of the overall quantum processor. Providing multi-layer stacked control circuits may increase the vertical dimension of the quantum processor and increase the efficiency of the horizontal arrangement of components.

### Example Control Circuits

Control circuits may include DAC circuits. DACs may include a Josephson junction, a superconducting loop, a communicative interface, and an energy storage component. In some implementations, the energy storage component may be formed from a high kinetic inductance material. In other implementations, the entire DAC may be formed from a high kinetic inductance material. The operation of Josephson junctions and/or CJJs in DACs is described in greater detail in, for example, U.S. Pat. Nos. 7,876,248 and 8,098,179.

FIG. 15 shows an example implementation of a DAC 1500 having an energy storage component 1502 that may be formed from a high kinetic inductance material. Storage component 1502 may be a high kinetic inductance film disposed entirely within a single fabrication layer of the quantum processor and may be substantially planar. Storage component 1502 may be provided with meanders as described in U.S. Pat. No. 11,127,893. Storage component 1502 may be a high kinetic inductance material as discussed above, and may include for example, WSi, MoN, NbN, NbTiN, TiN, or granular Aluminum. DAC 1500 has a superconducting loop 1504 that in operation carries a superconducting current. Superconducting loop 1504 may comprise any suitable superconducting materials such as, for example, niobium or aluminum. Superconducting loop 1504 is coupled to an inflow line 1506 and an outflow line 1508. Outflow line 1508 may optionally provide a current to other devices (e.g., by acting as an inflow line 5106 for other devices). For example, in some implementations, DACs are serially coupled together by inflow and outflow lines 1506, 1508, thereby providing current to a plurality of DACs. Superconducting loop 1504 is interrupted by one or more Josephson junctions. In the example implementation of FIG. 15, superconducting loop 1504 is interrupted by a compound Josephson junction (“CJJ”) 1510.

Superconducting loop 1504 is also interrupted by a control coupler 1512 and energy storage component 1502, which receive a superconducting current mediated by the state of CJJ 1510. Control coupler 1512 couples DAC 1500 to a target device 1514 (e.g., a qubit, a qubit coupler, and/or another controllable device of a quantum processor). In the example implementation of FIG. 15, control coupler 1512 forms an inductive connection between DAC 1500 and target device 1514. Energy storage component 1502 may be formed from a high kinetic inductance material and be connected to superconducting loop 1504, which may be formed from a material that is not a high kinetic inductance material. In some implementations, energy storage component 1502 and control coupler 1512 may be combined into a single element.

Referring to FIG. 15E, an implementation of a DAC similar to DAC 1500 will be discussed. Considering first stack 1402, superconducting loop 1504 may be formed in second wiring layer 1406, along with any respective control circuitry. Energy storage component 1502 may be formed in first wiring layer 1404, from high kinetic inductance material. The Josephson junctions of CJJ 1510 may be formed in Josephson junction layer 1438. Control coupler 1512 may be formed in second wiring layer 1406 and may be positioned to communicate with Josephson junction 1436, for example, in order to bias the JJ of a controllable device such as a qubit or coupler. It will be understood that the placement of the elements within the layers may be varied depending on the specific implementation. For example, Josephson junction layer 1438 may also contain superconducting loop 1504, with only control circuitry being formed in wiring layer 1412.

In alternative implementations, a DAC may be formed entirely in a high kinetic inductance material layer, with control circuitry being formed either within the same high kinetic inductance layer, or in a separate wiring layer. FIG. 16 shows a superconducting integrated circuit 1600 having a control device 1602 that may be a DAC formed from a single layer of high kinetic inductance material, for example, the high kinetic inductance material of first wiring layer 1404 or third wiring layer 1410 of FIG. 14A. DAC 1602 has a loop of material 1604 interrupted by Josephson junctions 1606, 1608, forming a CJJ. Each Josephson junction is formed from a restriction in the layer of high kinetic inductance material that provides non-linearity to the circuit. The restriction may, for example, be a narrowing of the layer of high kinetic inductance material, or a thinner portion or other barrier to linear transmission. A narrowed or thinner portion may be referred to as a neck or necked portion. It will be understood that additional Josephson junctions may also be included in some implementations to form compound-compound Josephson junctions within control device 1602. As used herein, compound-compound Josephson junction (CCJJ) refers to a Josephson Junction where one or more of the junctions within a compound Josephson junction is itself a compound Josephson junction. See, for example, International (PCT) Patent Application Publication Number WO2010/028183 for a detailed description of a qubit with a CCJJ.

Josephson junctions 1606, 1608 are electrically coupled between input 1610 and output 1612, which may optionally provide current to other devices. In some implementations, DACs are serially coupled together by input and outputs 1610, 1612, thereby providing current to a plurality of DACs. DAC 1602 further has a control coupler 1614 and an energy storage component 1616. In some implementations, energy storage component 1616 and control coupler 1614 are combined into a single element and energy storage component 1616 also provides an inductive coupler. Control circuitry 1620 may be provided to DAC 1602, and may, in some implementations, be formed in a separate layer, such as in one of layers 1406 and 1412 of FIGS. 14A-14G.

A controllable device 1618 may be coupled to control coupler 1614 of DAC 1602. For example, controllable device 1618 may be a qubit, and control coupler 1614 may inductively couple to provide control of the qubit. As shown, for example, in FIG. 14E, a qubit may be formed in a separate layer or layers 1442, 1418 with a trilayer Josephson junction. In other implementations, a qubit may be formed by a single layer of high kinetic inductance material as part of stack 1414. DAC 1602 may control a target device from a plurality of controllable devices, for example, a qubit as described previously, a coupler, or another device. Further detail on addressing and programming DACs can be found in Bunyk et al., Architectural considerations in the design of a superconducting quantum annealing processor (https://arxiv.org/pdf/1401.5504.pdf), International (PCT) Publication No. WO 2019/222514. Other addressing techniques may be used as will be understood by those of skill in the art.

It will be understood that while FIG. 15 and FIG. 16 show single stage DACs, the superconducting integrated circuits described herein may also include DACs with multiple stages. For example, the control device in any of the superconducting integrated circuits described herein may be a DAC having multiple interconnected stages. This may allow for greater range or control when controlling controllable devices. See, for example, the two stage DAC in Bunyk et al., Architectural considerations in the design of a superconducting quantum annealing processor (https://arxiv.org/pdf/1401.5504.pdf), U.S. Pat. No. 10,528,886, and U.S. Provisional Patent Application No. 63/136,987.

### Method

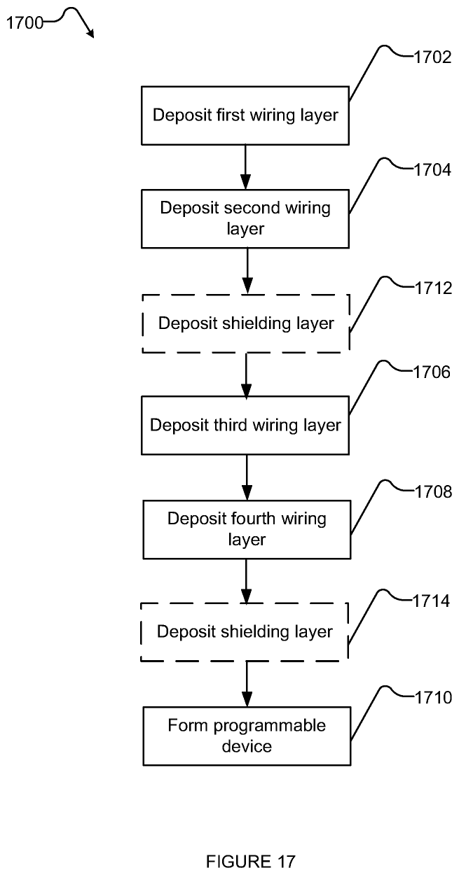

FIG. 17 is a flow chart illustrating a method 1700 for forming a superconducting integrated circuit in accordance with the present systems and methods. Method 1700 includes acts 1702-1710, although in other implementations certain acts may be omitted, additional acts may be added, and/or the acts may be performed in different orders. Method 1700 may be performed by, for example, integrated circuit fabrication equipment in response to an initiation of a fabrication process.

At 1702, a first superconducting wiring layer is deposited. The first wiring layer is formed from a high kinetic inductance material, as discussed above, and may be deposited using a variety of deposition techniques, such as electron beam lithography, vapor deposition, vacuum evaporation, and other cutting and patterning methods. As used herein, “depositing” may include both an initial formation operation where a uniform layer of material is deposited onto an underlying surface and subsequent patterning operations performed on the material to form wiring, devices, and other structures. It will be understood that similar deposition techniques may be used in the other depositing acts described herein. Depositing a first superconducting wiring layer may include forming a Josephson junction within the first high kinetic inductance material. This may, for example, include depositing a high kinetic inductance material, and then patterning at least a portion of the high kinetic inductance material to form a Josephson junction.

At 1704, a second superconducting wiring layer is deposited adjacent to and communicatively coupled with the first superconducting wiring layer to form a first control circuit. In some implementations the first superconducting wiring layer is deposited overlying the second superconducting wiring layer.

At 1706, a third superconducting wiring layer is deposited overlying the first superconducting wiring layer and the second superconducting wiring layer. The third superconducting wiring layer is formed from a second high kinetic inductance material. Depositing a third superconducting wiring layer may include forming a Josephson junction within the second high kinetic inductance material.

At 1708, a fourth superconducting wiring layer is deposited adjacent to and communicatively coupled with the third superconducting wiring layer to form a second control circuit. In some implementations the third superconducting wiring layer is deposited to overlie the fourth superconducting wiring layer.

At 1710, a controllable device is formed in an additional layer such that at least one of the first control circuit and the second control circuit is communicatively coupled to the controllable device. In some implementations, forming a controllable device includes depositing a trilayer. Act 1710 may include depositing multiple superconducting wiring layers, such as trilayer JJ layers in communication with wiring layers. Act 1710 may also include forming multiple controllable devices.

It will be understood that the order of acts 1702-1710 may be varied in other implementations. For example, act 1710 may come first, with the controllable device being formed in wiring layers that make up a stack deposited directly on and/or overlying a substrate. Acts 1702 and 1704 may then be performed, so that the first superconducting wiring layer is deposited overlying the controllable device. It will also be understood that the order of the layers forming each control circuit may be varied, with acts 1704 and 1708 occurring prior to acts 1702 and 1706 when forming the respective control circuit.

In some implementations, additional acts may be included in method 1700. Example acts are shown in broken lines at 1712 and 1714. At 1712, a superconducting shielding layer is deposited to separate the first superconducting wiring layer and the second superconducting wiring layer from the third superconducting wiring layer and the fourth superconducting wiring layer. At 1714, a superconducting shielding layer is deposited to separate the first superconducting wiring layer, the second superconducting wiring layer, the third superconducting wiring layer, and the fourth superconducting wiring layer from the additional layer. In other implementations, method 1700 may further include acts similar to 1702 and 1704 to form additional control circuits. For example, method 1700 may include depositing a fifth superconducting wiring layer overlying the third superconducting wiring layer and the fourth superconducting wiring layer, the fifth superconducting wiring layer being formed from a third high kinetic inductance material, and depositing a sixth superconducting wiring layer adjacent to and communicatively coupled with the fifth superconducting wiring layer to form a third control circuit.

In some implementations a trilayer is deposited adjacent to one of the first superconducting wiring layer and the third superconducting wiring layer, or a trilayer is deposited adjacent to each of the first superconducting wiring layer and the third superconducting wiring layer. In some implementations the trilayer deposited adjacent to a respective superconducting wiring layer is deposited overlying the respective superconducting wiring layer.

### Post-Amble

The above described method(s), process(es), or technique(s) could be implemented by a series of processor readable instructions stored on one or more nontransitory processor-readable media. Some examples of the above described method(s), process(es), or technique(s) method are performed in part by a specialized device such as an adiabatic quantum computer or a quantum annealer or a system to program or otherwise control operation of an adiabatic quantum computer or a quantum annealer, for instance a computer that includes at least one digital processor. The above described method(s), process(es), or technique(s) may include various acts, though those of skill in the art will appreciate that in alternative examples certain acts may be omitted and/or additional acts may be added. Those of skill in the art will appreciate that the illustrated order of the acts is shown for example purposes only and may change in alternative examples. Some of the example acts or operations of the above described method(s), process(es), or technique(s) are performed iteratively. Some acts of the above described method(s), process(es), or technique(s) may be performed during each iteration, after a plurality of iterations, or at the end of all the iterations.

The above description of illustrated implementations, including what is described in the Abstract, is not intended to be exhaustive or to limit the implementations to the precise forms disclosed. Although specific implementations of and examples are described herein for illustrative purposes, various equivalent modifications can be made without departing from the spirit and scope of the disclosure, as will be recognized by those skilled in the relevant art. The teachings provided herein of the various implementations can be applied to other methods of quantum computation, not necessarily the example methods for quantum computation generally described above.

The various implementations described above can be combined to provide further implementations. All of the commonly assigned U.S. patent application publications, U.S. patent applications, foreign patents, and foreign patent applications referred to in this specification and/or listed in the Application Data Sheet are incorporated herein by reference, in their entirety, including but not limited to: U.S. Pat. Nos. 11,127,893; 7,533,068; 7,876,248; 8,008,942; 8,098,179; 8,195,596; 8,190,548; 8,035,540; 8,421,053; 8,536,566; 9,015,215; 10,528,886; U.S. Patent Application Publication No. 2014/0344322; U.S. Patent Application Publication No. 2018/0101786; U.S. Patent Application Publication No. 2018/02219150A1; U.S. Patent Application Publication No. 2019/0019099A1; International (PCT) Patent Application Publication No. WO2012/064974; International (PCT) Patent Application Publication No. WO2010/028183; International (PCT) Patent Application Publication No. WO2017/192733; International (PCT) Patent Application Publication No. WO2019/222514; International (PCT) Patent Application Publication No. WO2020/168097; International (PCT) Patent Publication No. WO2021/231224A1; U.S. Provisional Patent Application No. 63/136,987; U.S. Provisional Patent Application No. 63/151,232; U.S. Provisional Patent Application No. 63/191,708; and U.S. Provisional Patent Application No. 63/194,364.

These and other changes can be made to the implementations in light of the above-detailed description. In general, in the following claims, the terms used should not be construed to limit the claims to the specific implementations disclosed in the specification and the claims, but should be construed to include all possible implementations along with the full scope of equivalents to which such claims are entitled. Accordingly, the claims are not limited by the disclosure.

1. A method of fabrication of a circuit comprising a superconducting device, the method comprising:
forming a first portion of the superconducting device on a first chip;
forming a second portion of the superconducting device on a second chip; and
bonding the first chip to the second chip, wherein the forming a first portion of the superconducting device on a first chip includes forming a dissipative portion of the superconducting device on the first chip, and the bonding the first chip to the second chip includes forming a superconductingly electrically communicative coupling between the first chip and the second chip.

2. The method of claim 1, wherein the forming a first portion of the superconducting device includes forming a first portion of a qubit.

3. The method of claim 2, wherein the forming a first portion of a qubit includes forming a first portion of a superconducting qubit.

4. The method of claim 3, wherein the forming a first portion of a superconducting qubit includes forming a first portion of a superconducting flux qubit.

5. The method of claim 3, wherein the forming a first portion of a superconducting qubit includes forming a first portion of a transmon.

6. The method of claim 1, wherein the circuit further comprises two qubits, and the forming a first portion of a superconducting device includes forming a first portion of a coupling device, the coupling device which is operable to provide communicative coupling between the two qubits.

7. The method of claim 1, wherein the forming a first portion of the superconducting device on a first chip and the forming a second portion of the superconducting device on a second chip includes the first chip has an upper surface with at least one contact pad and the second chip has an upper surface with at least one contact pad, and further comprising forming a flip-chip configuration in which the first chip is flipped relative to the second chip so that the upper surface of the first chip faces the upper surface of the second chip, and the at least one contact pad of the first chip is aligned with the at least one contact pad of the second chip.

8. The method of claim 7, wherein the bonding the first chip to the second chip includes forming a bump bond between the first chip and the second chip.

9. The method of claim 8, wherein the forming a bump bond between the first chip and the second chip includes forming an indium bump bond between the first chip and the second chip.

10. The method of claim 8, wherein the forming a bump bond between the first chip and the second chip includes superconductingly electrically coupling the bump bond to at least two superconducting devices on the first chip.

11. The method of claim 10, wherein the superconductingly electrically coupling the bump bond to at least two superconducting devices on the first chip includes superconductingly electrically coupling the bump bond to a ground, the ground which is common to each superconducting device of the at least two superconducting devices on the first chip.

12. The method of claim 7, further comprising:
forming a ground plane; and
superconductingly electrically coupling at least two superconducting devices on the first chip to the ground plane.

13. The method of claim 12, wherein forming a ground plane includes forming a ground plane in an upper layer of the second chip.

14. The method of claim 1, wherein the forming a dissipative portion of the superconducting device includes forming a shunt capacitor.

15. The method of claim 1, wherein the forming a first portion of the superconducting device on a first chip includes forming the first portion of the superconducting device on a chip which includes a substrate and a single metal layer, and the forming of a second portion of the superconducting device on a second chip includes forming the second portion of the superconducting device on a multi-layer chip.

16. The method of claim 15, wherein the forming the first portion of the superconducting device on a chip which includes a substrate and a single metal layer includes forming the first portion of the superconducting device on a substrate comprising at least one of sapphire and single-crystal silicon.

17. The method of claim 15, wherein the superconducting device is a qubit, and forming the second portion of the superconducting device on a multi-layer chip includes forming a qubit control circuit on the multi-layer chip.

18. A circuit comprising:
a first chip, the first chip comprising a first portion of a superconducting device;
a second chip, the second chip comprising a second portion of the superconducting device; and
a bond between the first chip and the second chip, the bond which superconductingly electrically communicatively couples the first portion of the superconducting device to the second portion of the superconducting device, wherein the first portion of the superconducting device is a dissipative portion of the superconducting device.

19. The circuit of claim 18, wherein the superconducting device is a qubit.

20. The circuit of claim 19, wherein the qubit is a superconducting qubit.

21. The circuit of claim 20, wherein the superconducting qubit is a superconducting flux qubit.

22. The circuit of claim 20, wherein the superconducting qubit is a transmon.

23. The circuit of claim 18, wherein the circuit further comprises two qubits, and the superconducting device is a coupling device, the coupling device which is operable to provide communicative coupling between the two qubits.

24. The circuit of claim 18, wherein the first chip has an upper surface with at least one contact pad, the second chip has an upper surface with at least one contact pad, and the first chip and the second chip are arranged in a flip-chip configuration in which the first chip is flipped relative to the second chip so that the upper surface of the first chip faces the upper surface of the second chip, and the at least one contact pad on the first chip is aligned with the at least one contact pad on the second chip.

25. The circuit of claim 24, wherein the bond is a bump bond.

26. The circuit of claim 25, wherein the bump bond comprises indium.

27. The circuit of claim 25, wherein the bump bond is superconductingly electrically communicatively coupled to at least two superconducting devices on the first chip.

28. The circuit of claim 27, wherein the bump bond is superconductingly electrically communicatively coupled to the at least two superconducting devices on the first chip by a ground, the ground which is common to each superconducting device of the at least two superconducting devices on the first chip.

29. The circuit of claim 24, further comprising a ground plane, the ground plane which is superconductingly electrically coupled to at least two superconducting devices on the first chip.

30. The circuit of claim 29, wherein the ground plane is a ground plane which is formed in an upper layer of the second chip.

31. The circuit of claim 18, wherein the dissipative portion of the superconducting device includes a shunt capacitor.

32. The circuit of claim 18, wherein the first chip includes a substrate and a single metal layer, and the second chip includes a multi-layer chip.

33. The circuit of claim 32, wherein the substrate comprises at least one of sapphire and single-crystal silicon.

34. The circuit of claim 32, wherein the second portion of the superconducting device includes a qubit control circuit on the multi-layer chip.

35. A circuit comprising:
a first chip comprising an upper surface with at least one contact pad, a first substrate and a ground plane overlying the first substrate; and
a second chip comprising a second substrate and multiple layers overlying the second substrate, an upper layer of the multi-layer chip comprising an upper surface with at least one contact pad, and a dissipative portion of a superconducting device, wherein the first chip and the second chip are arranged in a flip-chip configuration in which the first chip is flipped relative to the second chip so that the upper surface of the first chip faces the upper surface of the second chip, the first chip is placed in proximity to the second chip, and the ground plane of the first chip is separated from the dissipative portion of the superconducting device by at least one of an air gap and a vacuum.

36. The circuit of claim 35, wherein the dissipative portion of the superconducting device is a shunt capacitor.

37. The circuit of claim 35, wherein the first substrate comprises at least one of sapphire and single-crystal silicon.

38. A superconducting integrated circuit comprising:
a first superconductive wiring region, the first superconductive wiring region comprising a first material that has a first critical temperature at and below which the first material is superconductive;
a second superconductive wiring region overlying the first superconductive wiring region, the second superconductive wiring region comprising the first material;
a third superconductive wiring region overlying the second superconductive wiring region, the third superconductive wiring region comprising a second material that has a second critical temperature at and below which the second material is superconductive, the second critical temperature different from the first critical temperature; and
a fourth superconductive wiring region overlying the third superconductive wiring region, the fourth superconductive wiring region comprising the second material,
wherein the first superconductive wiring region and the second superconductive wiring region each comprise at least a portion of at least one noise-susceptible superconducting device.

39. The superconducting integrated circuit of claim 38 wherein the first critical temperature is lower than the second critical temperature.

40. The superconducting integrated circuit of claim 38 wherein the first material is a low-noise material.

41. The superconducting integrated circuit of claim 40 wherein the low-noise material is aluminum.

42. The superconducting integrated circuit of claim 38 wherein the second material is niobium.

43. The superconducting integrated circuit of claim 38 wherein the at least one noise-susceptible superconducting device is a qubit.

44. The superconducting integrated circuit of claim 43 wherein the qubit is a superconducting flux qubit comprising a loop of the first material interrupted by at least one Josephson junction.

45. The superconducting integrated circuit of claim 38 wherein the at least one noise-susceptible superconducting device is a coupler.

46. The superconducting integrated circuit of claim 45 wherein the coupler comprises a loop of the first material interrupted by at least one Josephson junction.

47. The superconducting integrated circuit of claim 38 wherein the fourth superconductive wiring region contains at least a portion of at least one digital-to-analog converter (DAC).

48. The superconducting integrated circuit of claim 47 wherein the at least one DAC comprises a loop of the second material interrupted by at least one Josephson junction.

49. The superconducting integrated circuit of claim 38 further comprising a kinetic inductance region overlying the third superconductive wiring region, the kinetic inductance region comprising a layer of high kinetic inductance material that has a respective critical temperature at and below which the high kinetic inductance material is superconductive and stores a larger proportion of current energy as kinetic energy than magnetic energy.

50. The superconducting integrated circuit of claim 49 wherein the high kinetic inductance material comprises at least one of: titanium nitride and niobium nitride.

51. The superconducting integrated circuit of claim 38 further comprising a kinetic inductance region disposed within the third superconductive wiring region, the kinetic inductance region comprising a layer of high kinetic inductance material that has a respective critical temperature at and below which the high kinetic inductance material is superconductive and stores a larger proportion of current energy as kinetic energy than magnetic energy.

52. The superconducting integrated circuit of claim 51 wherein the high kinetic inductance material comprises at least one of: titanium nitride and niobium nitride.

53. A method of fabricating a superconducting integrated circuit, the method comprising:
forming a first superconductive wiring region comprising a first material that has a first critical temperature at and below which the first material is superconductive;
forming a second superconductive wiring region overlying the first superconductive wiring region, the second superconductive wiring region comprising the first material;
forming a third superconductive wiring region overlying the second superconductive wiring region, the third superconductive wiring region comprising a second material that has a second critical temperature at and below which the second material is superconductive, the second critical temperature different from the first critical temperature; and
forming a fourth superconductive wiring region overlying the third superconductive wiring region, the fourth superconductive wiring region comprising the second material,
wherein forming the first superconductive wiring region and the second superconductive wiring region comprises forming at least a portion of at least one noise-susceptible superconducting device.

54. The method of claim 53 wherein forming a first superconductive wiring region comprising a first material that has a first critical temperature at and below which the first material is superconductive and forming a third superconductive wiring region overlying the second superconductive wiring region, the third superconductive wiring region comprising a second material has a second critical temperature at and below which the second material is superconductive comprises forming the first superconductive wiring region and the third superconductive wiring region from the first and second materials with the first critical temperature being lower than the second critical temperature.

55. The method of claim 53 wherein forming a first superconductive wiring region comprising a first material comprises forming the first superconductive wiring region comprising a low-noise material.

56. The method of claim 55 wherein forming the first superconductive wiring region comprising the low-noise material comprises forming the first superconductive wiring region comprising aluminum.

57. The method of claim 53 wherein forming the third superconductive wiring region comprising a second material comprises forming the third superconductive wiring region comprising niobium.

58. The method of claim 53 wherein forming at least a portion of at least one noise-susceptible superconducting device comprises forming at least one of: a qubit and a coupler.

59. The method of claim 53 wherein forming the fourth superconductive wiring region comprises forming at least a portion of at least one digital-to-analog converter (DAC).

60. The method of claim 53 further comprising forming a kinetic inductance region overlying the third superconductive wiring region, the kinetic inductance region comprising a layer of high kinetic inductance material that has a respective critical temperature at and below which the high kinetic inductance material is superconductive and causes a larger proportion of current energy stored in the kinetic inductance region to be stored as kinetic energy than magnetic energy.

61. The method of claim 60 wherein forming a layer of high kinetic inductance material that has a respective critical temperature at and below which the high kinetic inductance material is superconductive and causes a larger proportion of current energy stored in the kinetic inductance region to be stored as kinetic energy than magnetic energy comprises forming a layer of high kinetic inductance material comprising at least one of: titanium nitride and niobium nitride.

62. The method of claim 53 further comprising forming a kinetic inductance region disposed within the third superconductive wiring region, the kinetic inductance region comprising a layer of high kinetic inductance material that has a respective critical temperature at and below which the high kinetic inductance material is superconductive and causes a larger proportion of current energy stored in the kinetic inductance region to be stored as kinetic energy than magnetic energy.

63. The method of claim 62 wherein forming a layer of high kinetic inductance material that has a respective critical temperature at and below which the high kinetic inductance material is superconductive and causes a larger proportion of current energy stored in the kinetic inductance region to be stored as kinetic energy than magnetic energy comprises forming a layer of high kinetic inductance material comprising at least one of: titanium nitride and niobium nitride.

64. A superconducting integrated circuit comprising:
a substrate;
a first stack overlying the substrate, the first stack comprising a first superconducting wiring layer formed from a first high kinetic inductance material and a second superconducting wiring layer communicatively coupled to the first superconducting wiring layer to form a first control circuit;
a second stack overlying the substrate, the second stack comprising a third superconducting wiring layer formed from a second high kinetic inductance material and a fourth superconducting wiring layer communicatively coupled the third superconducting wiring layer to form a second control circuit, the second stack overlying the first stack; and
a third stack overlying the substrate, the third stack comprising a controllable device;
wherein at least one of the first control circuit and the second control circuit is communicatively coupled to the controllable device.

65. The superconducting integrated circuit of claim 64, wherein the first control circuit comprises a first digital-to-analog converter (DAC) and the second control circuit comprises a second DAC.

66. The superconducting integrated circuit of claim 64, wherein the controllable device is one of a qubit, a coupler, a parameter tuning device connected to a qubit or a coupler, or a readout device for a qubit.

67. The superconducting integrated circuit of claim 64, wherein the first stack and the second stack overlie the third stack.

68. The superconducting integrated circuit of claim 64, further comprising a superconducting shielding layer separating the first stack from the second stack.

69. The superconducting integrated circuit of claim 64, further comprising a superconducting shielding layer separating the first stack and the second stack from the third stack.

70. The superconducting integrated circuit of claim 64, wherein at least one of the first stack and the second stack comprises a Josephson junction layer comprising one or more trilayer Josephson junctions.

71. The superconducting integrated circuit of claim 70, wherein at least one of the first superconducting wiring layer and the third superconducting wiring layer are adjacent to the Josephson junction layer.

72. The superconducting integrated circuit of claim 70, wherein each of the first stack and the second stack comprises a respective Josephson junction layer comprising one or more trilayer Josephson junctions.

73. The superconducting integrated circuit of claim 64, wherein the third stack comprises a Josephson junction layer comprising one or more trilayer Josephson junctions.

74. The superconducting integrated circuit of any one of claims 70 through 73, wherein each Josephson junction layer is formed in a top layer of the respective stack.

75. The superconducting integrated circuit of claim 64, wherein at least one of the first superconducting wiring layer and the third superconducting wiring layer comprises a respective Josephson junction formed from the respective high kinetic inductance material.

76. The superconducting integrated circuit of claim 75, wherein each of the first superconducting wiring layer and the third superconducting wiring layer comprises respective a Josephson junction formed from the respective high kinetic inductance material.

77. The superconducting integrated circuit of one of claim 75 and claim 76, wherein the first superconducting wiring layer and the third superconducting wiring layer comprises a respective top layer of the respective stack.

78. The superconducting integrated circuit of claim 64, wherein the first high kinetic inductance material and the second high kinetic inductance material have at least 10% of energy stored in the respective high kinetic inductance material stored as kinetic inductance.

79. The superconducting integrated circuit of claim 64, wherein the first high kinetic inductance material and the second high kinetic inductance material have respective kinetic inductance fractions of 0.1<α≤1.

80. The superconducting integrated circuit of claim 64, wherein the first high kinetic inductance material and the second high kinetic inductance material comprise one of WSi, MoN, NbN, NbTiN, TiN, and granular Aluminum.

81. The superconducting integrated circuit of claim 64, further comprising a fourth stack comprising a fifth superconducting wiring layer and a sixth superconducting wiring layer, the fifth superconducting wiring layer formed from a third high kinetic inductance material, the fifth superconducting wiring layer and the sixth superconducting wiring layer communicatively coupled to form a third control circuit, the fourth stack overlying the first stack and the second stack.

82. The superconducting integrated circuit of claim 64, wherein the third stack comprises multiple controllable devices.

83. The superconducting integrated circuit of claim 64, wherein the third stack comprises multiple layers.

84. The superconducting integrated circuit of claim 64, wherein at least one of the second superconducting wiring layer and the fourth superconducting wiring layer comprise one of niobium and aluminum.

85. The superconducting integrated circuit of claim 64, wherein at least one of the first control circuit and the second control circuit comprises control coupler wiring that extends from the respective one of the first stack or the second stack into the third stack, and wherein at least one of the first control circuit and the second control circuit is communicatively coupled to the controllable device via a galvanic or inductive coupling between the control coupler wiring and the controllable device.

86. The superconducting integrated circuit of claim 64, wherein the controllable device comprises controllable coupler wiring that extends from the third stack into the respective one of the first stack or the second stack, and wherein at least one of the first control circuit and the second control circuit is communicatively coupled to the controllable device via a galvanic or inductive coupling between the controllable coupler wiring and the at least one of the first control circuit and the second control circuit.

87. The superconducting integrated circuit of one of claims 85 and 86, wherein:
the first control circuit and the second control circuit each comprise a respective DAC;
the first superconducting wiring layer and the third superconducting wiring layer each include a storage inductor of the respective DAC;
the second superconducting wiring layer and the fourth superconducting wiring layer each include control circuitry for the respective DAC; and
each of the first stack and the second stack comprises one or more Josephson junctions of the respective DAC.

88. A method of forming a superconducting integrated circuit, the method comprising:
depositing a first superconducting wiring layer comprising a first high kinetic inductance material;
depositing a second superconducting wiring layer such that the second superconducting wiring layer is positioned to communicatively couple with the first superconducting wiring layer to form a first control circuit;
depositing a third superconducting wiring layer overlying the first superconducting wiring layer and the second superconducting wiring layer, the third superconducting wiring layer comprising a second high kinetic inductance material;
depositing a fourth superconducting wiring layer such that the fourth superconducting wiring layer is positioned to communicatively couple with the third superconducting wiring layer to form a second control circuit; and
forming a controllable device in an additional layer such that at least one of the first control circuit and the second control circuit is communicatively coupled to the controllable device.

89. The method of claim 88, wherein depositing a first superconducting wiring layer comprises depositing the first superconducting wiring layer overlying the controllable device.

90. The method of claim 88, wherein forming a controllable device comprises forming the controllable device overlying a substrate.

91. The method of claim 88, further comprising depositing a superconducting shielding layer to separate the first superconducting wiring layer and the second superconducting wiring layer from the third superconducting wiring layer and the fourth superconducting wiring layer.

92. The method of claim 88, further comprising depositing at least one superconducting shielding layer to separate the first superconducting wiring layer, the second superconducting wiring layer, the third superconducting wiring layer, and the fourth superconducting wiring layer from the additional layer.

93. The method of claim 88, wherein forming a controllable device includes depositing a trilayer.

94. The method of claim 88, further comprising depositing a trilayer adjacent to one of the first superconducting wiring layer and the third superconducting wiring layer.

95. The method of claim 88, further comprising depositing a respective trilayer adjacent to each of the first superconducting wiring layer and the third superconducting wiring layer.

96. The method of one of claim 94 and claim 95, wherein depositing a respective trilayer adjacent to a respective superconducting wiring layer comprises depositing the trilayer overlying the respective superconducting wiring layer.

97. The method of claim 88, further comprising forming a Josephson junction at least partially within the first high kinetic inductance material of the first superconducting wiring layer.

98. The method of claim 88, further comprising forming a Josephson junction at least partially within the second high kinetic inductance material of the third superconducting wiring layer.

99. The method of claim 88, wherein depositing a first superconducting wiring layer comprises depositing the first superconducting wiring layer to overlie the second superconducting wiring layer, and wherein depositing a third superconducting wiring layer comprises depositing the third superconducting wiring layer to overlie the fourth superconducting wiring layer.

100. The method of claim 88, further comprising:
depositing a fifth superconducting wiring layer overlying the third superconducting wiring layer and the fourth superconducting wiring layer, the fifth superconducting wiring layer comprising a third high kinetic inductance material; and
depositing a sixth superconducting wiring layer adjacent to and communicatively coupled with the fifth superconducting wiring layer to form a third control circuit.

101. The method of claim 88, wherein forming a controllable device comprises forming multiple controllable devices.

102. The method of claim 88, wherein forming a controllable device comprises depositing multiple superconducting wiring layers.

103. The method of claim 88, wherein forming a controllable device in an additional layer such that at least one of the first control circuit and the second control circuit is communicatively coupled to the controllable device includes depositing coupling wiring that extends from the respective one of the second superconducting wiring layer and the fourth superconducting wiring layer into the additional layer to provide a galvanic or inductive coupling between the coupling wiring and the controllable device.

104. The method of claim 88, wherein forming a controllable device in an additional layer such that at least one of the first control circuit and the second control circuit is communicatively coupled to the controllable device includes depositing coupling wiring that extends from the additional layer to the respective one of the second superconducting wiring layer and the fourth superconducting wiring layer to provide a galvanic or inductive coupling between the coupling wiring and the at least one of the first control circuit and the second control circuit.

105. The method of one of claims 103 and 104, wherein:
depositing a first superconducting wiring layer and depositing a third superconducting wiring layer each comprise at least part of forming at least a portion of a storage inductor of a respective DAC; and
depositing a second superconducting wiring layer and a fourth superconducting wiring layer each comprise at least part of forming at least a portion of control circuitry for the respective DAC.

106. The method of claim 105, wherein depositing a first superconducting wiring layer and depositing a third superconducting wiring layer each comprise at least part of forming at least a portion of a Josephson junction of the respective DAC.

107. The method of claim 105, further comprising depositing at least a portion of a Josephson junction of the respective DAC in a layer adjacent to each of the first superconducting wiring layer and the third superconducting wiring layer.
